(19) United States
(12) Patent Application Publication
(10) Pub. No.: US 2013/0286292 A1
(43) Pub. Date: Oct. 31, 2013

(54) TELEVISION RECEIVER AND ELECTRONIC APPARATUS

(71) Applicant: KABUSHIKI KAISHA TOSHIBA, Tokyo (JP)

(72) Inventors: Akifumi YAMAGUCHI, Tokyo (JP); Koji KONNO, Tokyo (JP)

(73) Assignee: KABUSHIKI KAISHA TOSHIBA, Tokyo (JP)

(21) Appl. No.: 13/734,563

(22) Filed: Jan. 4, 2013

(30) Foreign Application Priority Data
Apr. 27, 2012 (JP) 2012-103877

(51) Int. Cl. H04N 5/44; H05K 7/20

(52) U.S. Cl. CPC H04N 5/44; H05K 7/20136
USPC 348/725; 361/692

(57) ABSTRACT

According to one embodiment, a television receiver includes: a housing comprising an air intake vent and an air exhaust vent; a circuit board device in the housing; a fan in the housing, the fan configured to supply airflow to the circuit board device; an elastic member configured to be placed in an opening of the housing or inside the housing; and a flexible sheet-like first member in the housing at a position where the flexible sheet-like first member covers at least a part of the opening, the flexible sheet-like first member configured to support the elastic member.

### CROSS-REFERENCE TO RELATED APPLICATIONS

This application is based upon and claims the benefit of priority from Japanese Patent Application No. 2012-103877, filed on Apr. 27, 2012; the entire contents of which are incorporated herein by reference.

### FIELD

Embodiments described herein relate generally to a television receiver and an electronic apparatus.

### BACKGROUND

Electronic apparatuses have been known in which parts housed in their housings provided with air intake vents and air exhaust vents are cooled by air supplied by fans.

In this type of electronic apparatuses such as television receivers, leaking of cooling air supplied by the fans from openings provided to the housings may lower cooling efficiency of the fans.

### BRIEF DESCRIPTION OF THE DRAWINGS

A general architecture that implements the various features of the invention will now be described with reference to the drawings. The drawings and the associated descriptions are provided to illustrate embodiments of the invention and not to limit the scope of the invention.

FIG. 1 is an exemplary perspective view of an electronic apparatus according to a first embodiment;

FIG. 2 is an exemplary plan view illustrating a lower wall of the electronic apparatus illustrated in FIG. 1;

FIG. 3 is an exemplary perspective view illustrating the lower wall and a peripheral wall of the electronic apparatus illustrated in FIG. 1;

FIG. 4 is an exemplary plan view illustrating the inside of the electronic apparatus illustrated in FIG. 1;

FIG. 5 is an exemplary perspective view illustrating the inside of the electronic apparatus illustrated in FIG. 1;

FIG. 6 is an exemplary perspective view illustrating the inside of the lower wall of the electronic apparatus illustrated in FIG. 1;

FIG. 7 is an exemplary perspective view illustrating the inside of an upper wall of the electronic apparatus illustrated in FIG. 1;

FIG. 8 is an exemplary plan view illustrating the inside of the electronic apparatus illustrated in FIG. 1;

FIG. 9 is an exemplary schematic cross-sectional view along line F9-F9 of the electronic apparatus illustrated in FIG. 8;

FIG. 10 is an exemplary cross-sectional view along line F10-F10 of the electronic apparatus illustrated in FIG. 8;

FIG. 11 is an exemplary cross-sectional view along line F11-F11 of the electronic apparatus illustrated in FIG. 8;

FIG. 12 is an exemplary cross-sectional view along line F12-F12 of the electronic apparatus illustrated in FIG. 8;

FIG. 13 is an exemplary schematic cross-sectional view illustrating the inside of the electronic apparatus illustrated in FIG. 8;

FIG. 14 is an exemplary schematic cross-sectional view along line F14-F14 of FIG. 13, illustrating the inside of the electronic apparatus illustrated in FIG. 13;

FIG. 15 is an exemplary schematic cross-sectional view illustrating a duct structure of the electronic apparatus illustrated in FIG. 8;

FIG. 16 is an exemplary schematic cross-sectional view illustrating the duct structure of the electronic apparatus illustrated in FIG. 8;

FIG. 17 is an exemplary perspective view illustrating a closing structure of the electronic apparatus illustrated in FIG. 6;

FIG. 18 is an exemplary plan view illustrating the closing structure of the electronic apparatus illustrated in FIG. 6;

FIG. 19 is an exemplary perspective view illustrating the closing structure in a closed state for explaining the closing structure of the electronic apparatus illustrated in FIG. 6;

FIG. 20 is an exemplary plan view illustrating the closing structure in the closed state for explaining the closing structure of the electronic apparatus illustrated in FIG. 6;

FIG. 21 is an exemplary cross-sectional view illustrating a duct structure according to a first modification of the first embodiment;

FIG. 22 is an exemplary cross-sectional view illustrating a duct structure according to a second modification of the first embodiment;

FIG. 23A is an exemplary cross-sectional view illustrating a duct structure according to a third modification of the first embodiment;

FIG. 23B is an exemplary exploded cross-sectional view illustrating the duct structure according to the third modification of the first embodiment;

FIG. 24 is an exemplary cross-sectional view illustrating a duct structure according to a fourth modification of the first embodiment;

FIG. 25 is an exemplary cross-sectional view illustrating a fan according to a fifth modification of the first embodiment;

FIG. 26 is an exemplary cross-sectional view illustrating the inside of the electronic apparatus according to a sixth modification of the first embodiment;

FIG. 27 is an exemplary cross-sectional view illustrating the inside of the lower wall of the electronic apparatus according to a seventh modification of the first embodiment;

FIG. 28 is an exemplary schematic plan view illustrating a region A of FIG. 27;

FIG. 29 is an exemplary cross-sectional view illustrating the inside of the electronic apparatus according to an eighth modification of the first embodiment;

FIG. 30 is an exemplary cross-sectional view illustrating a duct structure according to a ninth modification of the first embodiment;

FIG. 31 is an exemplary cross-sectional view illustrating a duct structure according to a tenth modification of the first embodiment;

FIG. 32 is an exemplary cross-sectional view illustrating the inside of the electronic apparatus according to an eleventh modification of the first embodiment;

FIG. 33 is an exemplary cross-sectional view illustrating the inside of the electronic apparatus according to a twelfth modification of the first embodiment;

FIG. 34 is an exemplary cross-sectional view illustrating the inside of the electronic apparatus according to a thirteenth modification of the first embodiment;

FIG. 35 is an exemplary cross-sectional view illustrating the inside of the electronic apparatus according to a fourteenth modification of the first embodiment;

FIG. 36 is an exemplary cross-sectional view illustrating the inside of the electronic apparatus according to the fourteenth modification of the first embodiment;

FIG. 37 is an exemplary perspective view of a television receiver according to a second embodiment;

FIG. 38 is an exemplary side view illustrating a part of the television receiver illustrated in FIG. 37;

FIG. 39 is an exemplary side view illustrating a closing structure of openings of the television receiver illustrated in FIG. 37;

FIG. 40 is an exemplary cross-sectional view along line F40-F40 of the electronic apparatus illustrated in FIG. 38;

FIG. 41 is an exemplary perspective view of an electronic apparatus according to a third embodiment when viewed from a front side of the electronic apparatus;

FIG. 42 is an exemplary perspective view of the electronic apparatus in the third embodiment when viewed from a rear side of the electronic apparatus; and

FIG. 43 is an exemplary perspective view of an electronic apparatus according to a fourth embodiment.

### DETAILED DESCRIPTION

In general, according to one embodiment, A television receiver comprises: a housing comprising an air intake vent and an air exhaust vent; a circuit board device in the housing; a fan in the housing, the fan configured to supply airflow to the circuit board device; an elastic member configured to be placed in an opening of the housing or inside the housing; and a flexible sheet-like first member in the housing at a position where the flexible sheet-like first member covers at least a part of the opening, the flexible sheet-like first member configured to support the elastic member.

A plurality of exemplary embodiments and modifications described below comprise identical elements. The same elements are labeled with the same reference numerals and duplicated descriptions are omitted. Corresponding parts among the embodiments and the modifications are replaceable with each other.

In the following embodiments, a television receiver, a personal computer, and a projector are described as examples of an electronic apparatus. The electronic apparatuses according to the embodiments, however, are not limited to them. Examples of the electronic apparatus according to the embodiments include various types of electronic apparatuses, such as smartphones, smartbooks, cellular phones, personal digital assistants (PDAs), videophone devices, image display control devices, and information storage devices.

### First Embodiment

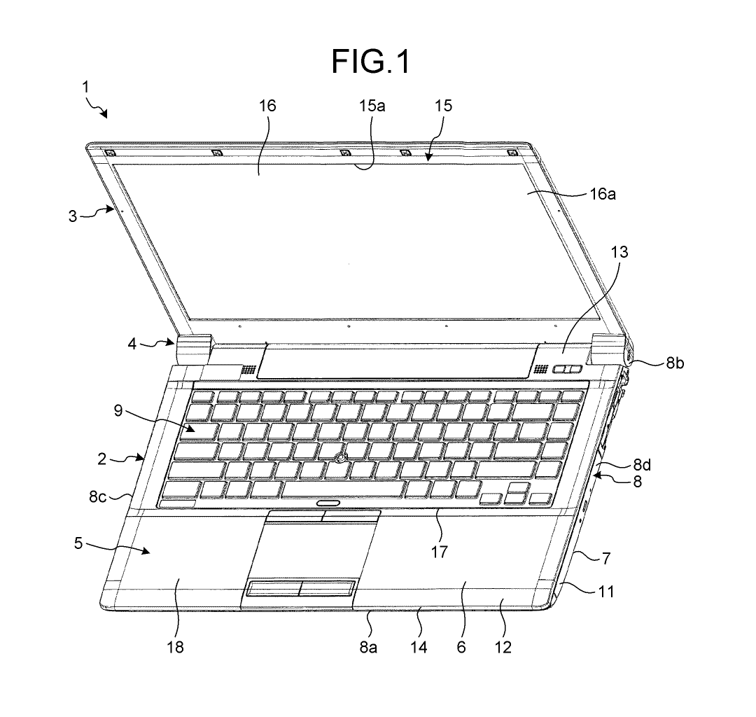

An electronic apparatus 1 according to a first embodiment is a so-called notebook personal computer. As illustrated in FIG. 1, the electronic apparatus 1 comprises a main body unit 2, a display unit 3, and a hinge 4. The main body unit 2 is the main body of the electronic apparatus 1 and includes a main board. The main body unit 2 comprises a housing 5. The housing 5 comprises an upper wall 6, a lower wall 7, and a peripheral wall 8 and is formed in a flat box shape.

The lower wall 7 faces a top surface of a desk when the electronic apparatus 1 is placed on the desk. The lower wall 7 is approximately in parallel with the top surface of the desk. The upper wall 6 extends approximately in parallel with the lower wall 7 (i.e., approximately in a horizontal direction) with a space between itself and the lower wall 7. A keyboard 9 is attached to the upper wall 6. The peripheral wall 8 stands upward from the lower wall 7 and extends between rims of the lower wall 7 and the upper wall 6.

The housing 5 comprises a base 11 and a cover 12. The base 11 comprises the lower wall 7 and a part of the peripheral wall 8. The cover 12 comprises the upper wall 6 and a part of the peripheral wall 8. The housing 5 is formed by assembling the cover 12 to the base 11.

The housing 5 has a rear edge 13 (a first edge) to which the display unit 3 is rotatably connected and a front edge (a second edge) located opposite the rear edge 13. The peripheral wall 8 comprises a front wall 8a, a rear wall 8b, a left side wall 8c, and a right side wall 8d. The front wall 8a extends in a width direction (a left-right direction) of the housing 5 at the front edge 14. The rear wall 8b extends in the width direction of the housing 5 at the rear edge 13. The left side wall 8c and the right side wall 8d respectively extend between the edges of the front wall 8a and the rear wall 8b in a length direction (a front-back direction) of the housing 5.

The display unit 3 is rotatably (so as to be capable of being opened and closed) connected by the hinge 4 to the rear edge 13 of the main body unit 2. The display unit 3 is rotatable between a closed position in which the display unit 3 is folded so as to cover the main body unit 2 and an open position in which the display unit 3 is unfolded from the main body unit 2.

As illustrated in FIG. 1, the display unit 3 comprises a display housing 15 and a display panel 16 housed in the display housing 15. A display screen 16a of the display panel 16 can be exposed to the outside through an opening 15a provided to the front wall of the display housing 15.

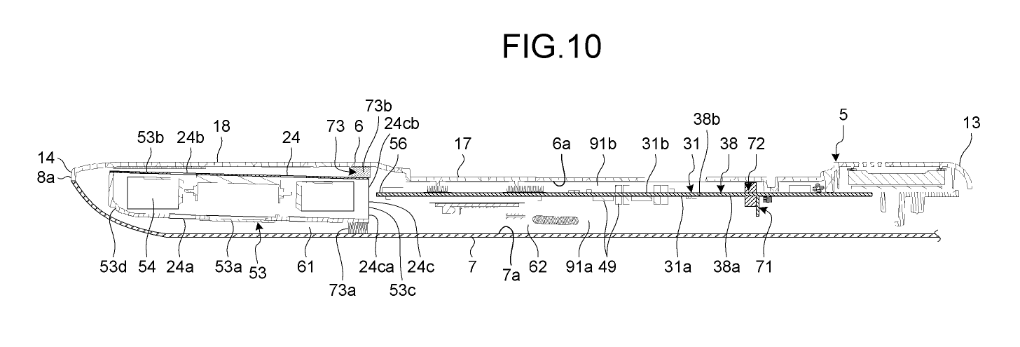

As illustrated in FIG. 1, the upper wall 6 comprises a keyboard placement section 17 to which the keyboard 9 is attached and a palm rest 18. The palm rest 18 is provided on a side closer to the front wall 8a than the keyboard placement section 17, that is, between the keyboard placement section 17 and the front wall 8a. As illustrated in FIG. 10, the keyboard placement section 17 is depressed toward the inside of the housing 5 so as to be lower than the palm rest 18. As a result, the top surface of the keyboard 9 attached to the keyboard placement section 17 is located approximately equal to or a bit higher than the top surface of the palm rest 18.

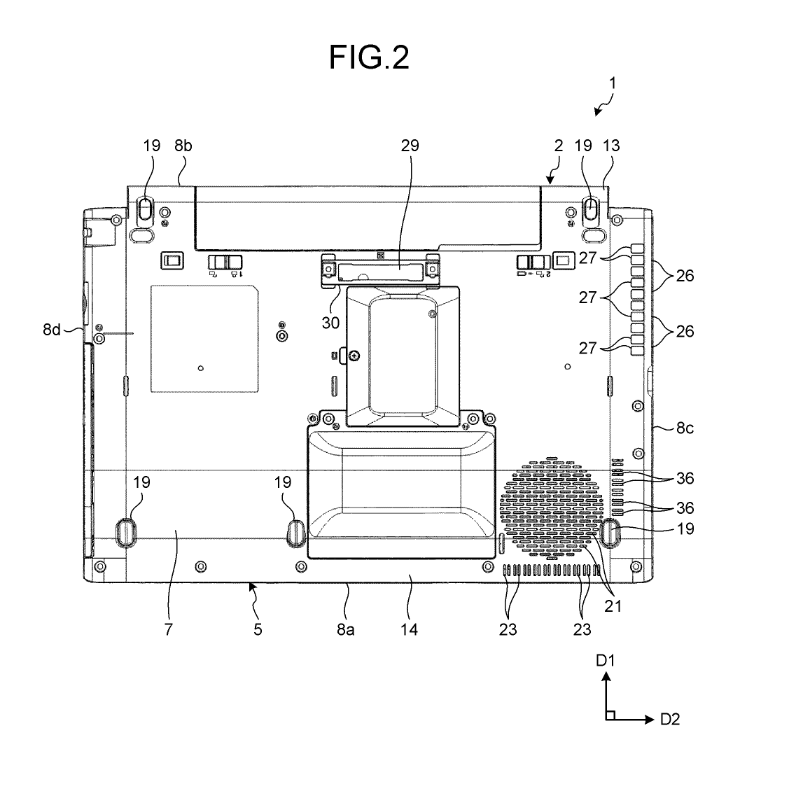

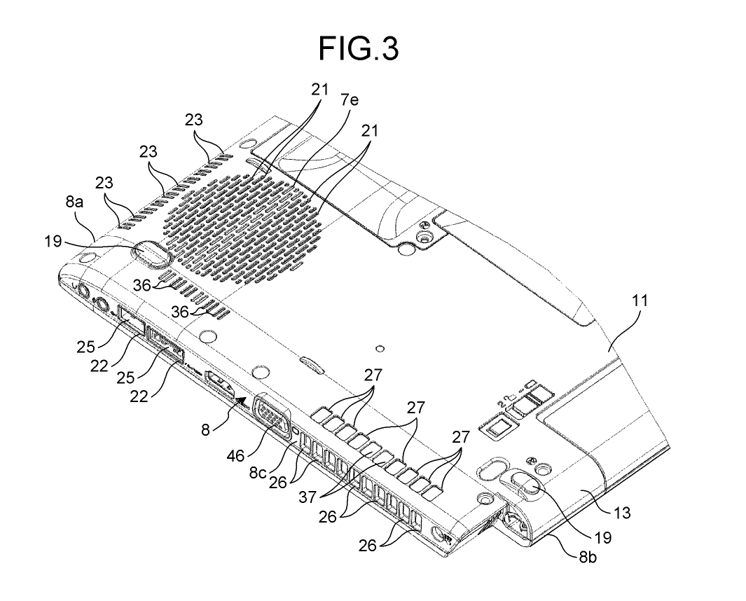

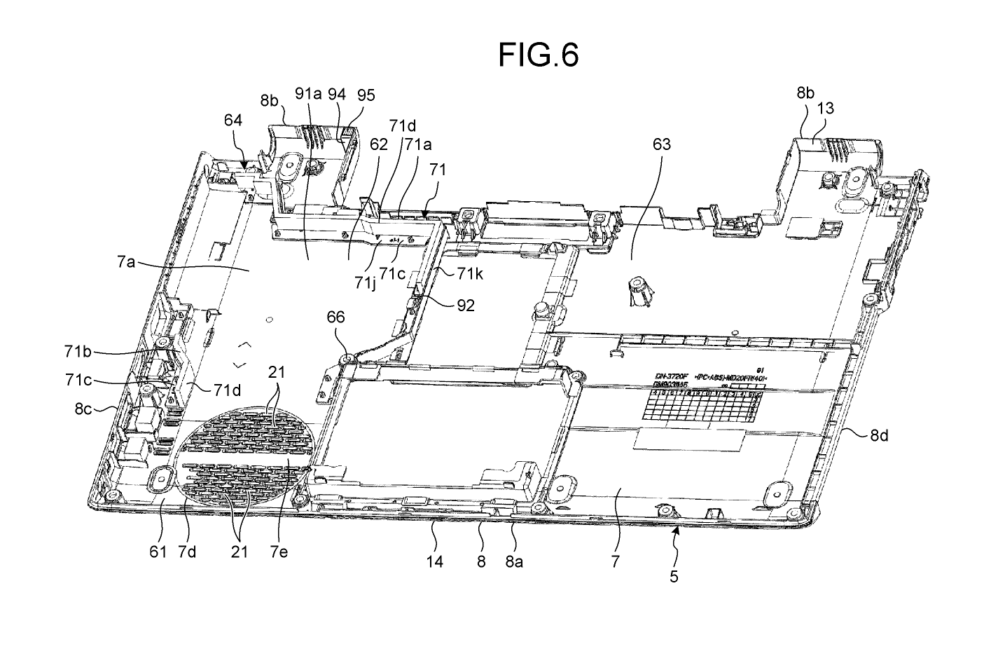

As illustrated in FIG. 2, the lower wall 7 of the housing 5 is provided with a plurality of legs 19. The legs 19 make contact with the top surface of the desk, whereby the lower wall 7 of the housing 5 is supported at a position away from the top surface of the desk by the legs 19. As illustrated in FIGS. 2 and 3, the housing 5 comprises first air intake vents 21, second air intake vents 22 (refer to FIG. 3), third air intake vents 23, and fourth air intake vents 36. The first air intake vents 21, the second air intake vents 22, the third air intake vents 23, and the fourth air intake vents 36 are apart from each other and provided to the left front edge of the housing 5 in a concentrated manner, for example. As illustrated in FIG. 6, the first air intake vents 21 are provided within a circular section with opposing halves 7d provided to the lower wall 7 of the housing 5. The circular section with opposing halves 7d faces a fan 24 (a cooling fan or an air supply mechanism). The circular section with opposing halves 7d has a traversing portion 7e, an inner surface of which a harness for the fan 24 is attached to. The traversing portion 7e thus covers the harness.

As illustrated in FIG. 2, the first air intake vents 21, the third air intake vents 23, and the fourth air intake vents 36 are provided to the lower wall 7. The first air intake vents 21 are located under the fan 24, which is described later, and face the fan 24. The third air intake vents 23 are located off the position under the fan 24 and have openings at positions between the first air intake vents 21 and the front wall 8a. The fourth air intake vents 36 are located under the fan 24 and have openings at positions between the first air intake vents 21 and the left side wall 8c.

As illustrated in FIG. 3, the second air intake vents 22 are provided to the left side wall 8c. The second air intake vents 22 serve as openings exposing various connectors 25. The second air intake vents 22 cause fresh air to flow into the housing 5 through gaps between the connectors 25 and the housing 5.

As illustrated in FIG. 3, the housing 5 comprises first air exhaust vents 26 and second air exhaust vents 27. The first air exhaust vents 26 are provided to the left side wall 8c at the rear edge 13 of the housing 5 so as to be located from a side adjacent to the side of the keyboard 9 to a side adjacent to the rear of the keyboard 9, for example. The first air exhaust vents 26 face a side of a heat sink 28, which is described later. The second air exhaust vents 27 are provided to the lower wall 7 at the rear edge 13 of the housing 5 and face the heat sink 28 from beneath. The second air exhaust vents 27 are provided along the front-back direction. A plurality of recesses 37 are formed between the second air exhaust vents 27 along the front-back direction. The recesses 37 do not penetrate the lower wall 7. The size of the recess 37 is approximately equal to that of the second air exhaust vent 27 in plan view. A claw that engages with the cover 12 is provided to an area near the recess 37 of the base 11. The recesses 37 increase stiffness of the base 11 near the claw. As illustrated in FIG. 2, the lower wall 7 is provided with an opening 30 exposing a docking connector 29.

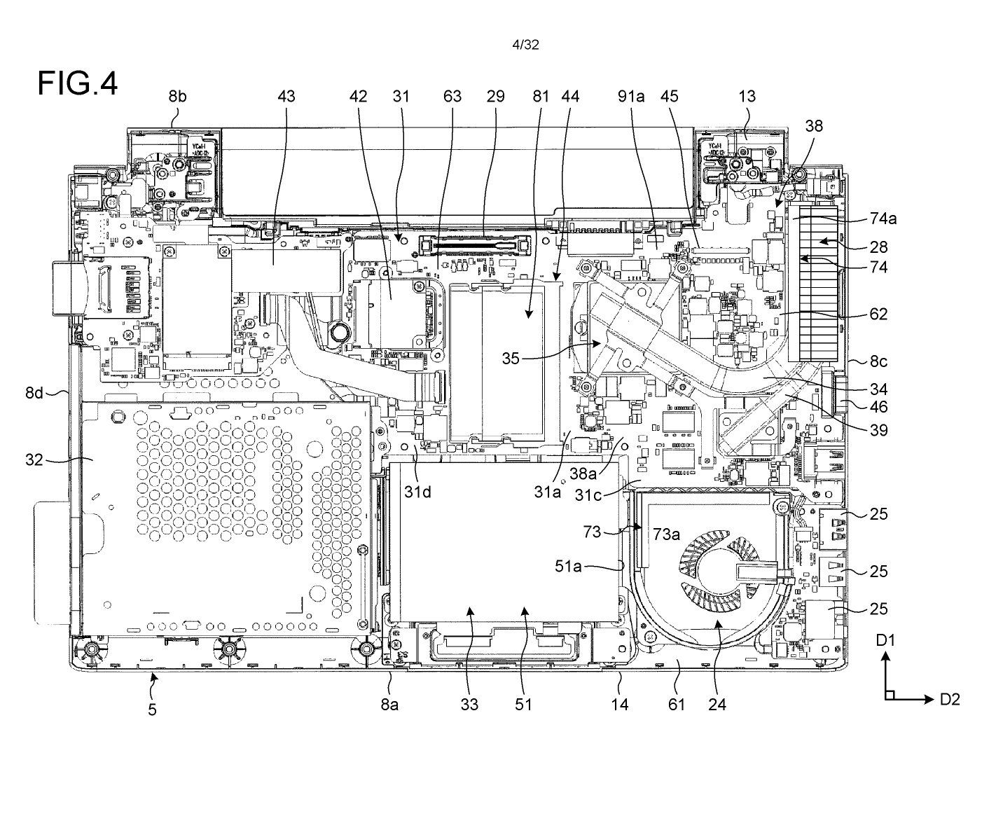

As illustrated in FIG. 4, the housing 5 houses a circuit board 31, an optical disk drive (ODD) 32, a storage device 33, the heat sink 28, a heat pipe 34, a heat dissipation plate 35, and the fan 24. The circuit board 31 is the main board, for example.

As illustrated in FIG. 10, the circuit board 31 has a first surface 31a and a second surface 31b located opposite the first surface 31a. The first surface 31a is the lower surface of the circuit board 31, for example. The second surface 31b is the upper surface of the circuit board 31, for example. Alternatively, the first surface 31a may be the upper surface and the second surface 31b may be the lower surface.

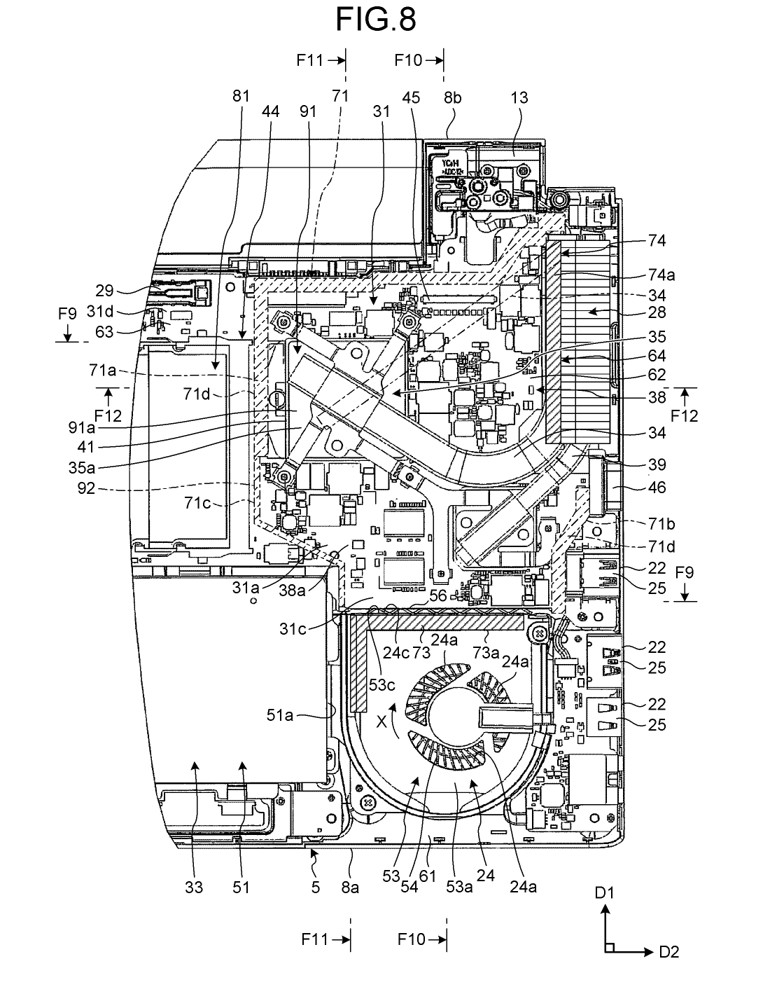

As illustrated in FIGS. 4 and 8, on the first surface 31a of the circuit board 31, a central processing unit (CPU) 41, a platform controller hub (PCH) 42, a power source circuit part 43, a memory slot connector 44, a liquid crystal display (LCD) connector 45, an input/output (I/O) connector 46, and electronic parts such as a first power source coil and a second power source coil are mounted.

The circuit board 31 forms a circuit board device 38 together with the mounted electronic parts such as the CPU 41 and the PCH 42, and is housed in the housing 5. The circuit board device 38 has a first section 38a that comprises the first surface 31a of the circuit board 31, and a second section 38b (refer to FIG. 10) that comprises the second surface 31b of the circuit board 31 and is located opposite the first section 38a. An upper inner surface of the housing 5 comprises an inner surface 6a of the upper wall 6 while a lower inner surface of the housing 5 comprises an inner surface 7a of the lower wall 7. The circuit board device 38 is disposed between the inner surface 6a and the inner surface 7a.

The CPU 41 is an example of a first heating element and the part producing the largest heat amount among the parts in the circuit board 31. The PCH 42 is an example of a second heating element. The PCH 42 is cooled by natural heat dissipation, for example. The power source circuit part 43 is an example of a third heating element and the part producing a relatively large heat amount among the parts in the circuit board 31.

As illustrated in FIG. 10, power source circuit parts 49 are mounted on the second surface 31b of the circuit board 31. The power source circuit parts 49 are examples of the heating element. The heating elements mounted on the circuit board 31 are not limited to the power source circuit parts 49.

As illustrated in FIG. 4, a direction from the front edge 14 toward the rear edge 13 of the housing 5 is defined as a first direction D1. In addition, a direction approximately orthogonal to the first direction D1 and from the right side wall 8d toward the left side wall 8c is defined as a second direction D2. A discharge outlet 24c of the fan 24, which is described later, has openings in the first direction D1.

In the description, the directions (up, down, left, and right) are defined on the basis of the normal posture (the posture in FIG. 1) of the electronic apparatus 1. Therefore, the expressions of the up-down and left-right differ from (are opposite to) those definitions in the descriptions using FIGS. 2, 4, 5, and 7, for example, in each of which the electronic apparatus 1 is illustrated in a reversed manner.

As illustrated in FIG. 10, the circuit board 31 is disposed under the keyboard placement section 17. As illustrated in FIG. 4, the circuit board 31 has a first section 31c located between the fan 24 and the heat sink 28 and a second section 31d located off the area between the fan 24 and the heat sink 28.

The fan 24 faces the first section 31c in an opening direction (the first direction D1) of the discharge outlet 24c of the fan 24. That is, the first section 31c is directly exposed to cooling wind discharged from the fan 24. The first section 31c also faces the heat sink 28 in the second direction D2. On the other hand, the second section 31d does not face the fan 24 in the opening direction of the discharge outlet 24c of the fan 24.

The CPU 41 and the power source circuit part 43 are mounted on the first section 31c of the circuit board 31 and located between the heat sink 28 and the fan 24. The PCH 42 is mounted on the second section 31d of the circuit board 31 and is off the area between the heat sink 28 and the fan 24.

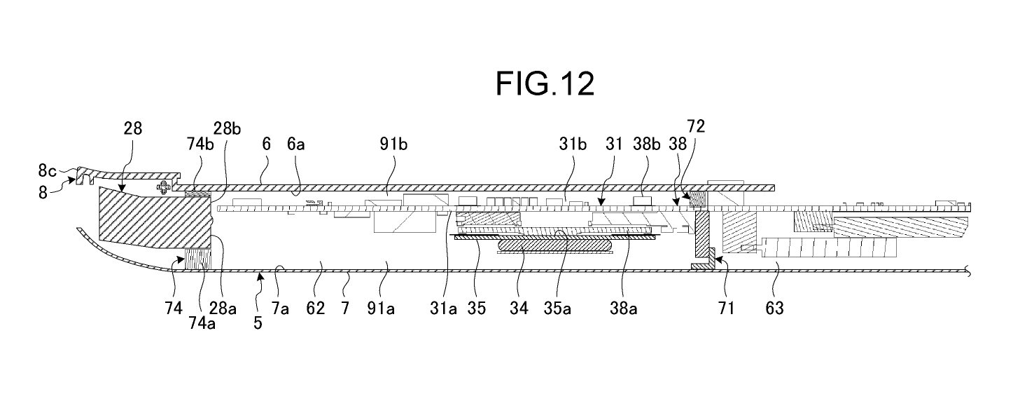

The heat sink 28 illustrated in FIGS. 4 and 12 is an example of a heat dissipation module. For example, the heat sink 28 is a fin unit comprising a plurality of fins. The heat sink 28 is disposed at the rear edge 13 of the housing 5 and faces the first air exhaust vents 26 of the housing 5. The heat sink 28 is located under the keyboard placement section 17. The gaps between the fins of the heat sink 28 open toward the first air exhaust vents 26. The heat pipe 34 and a second heat pipe 39 are connected to the heat sink 28. The heat sink 28 is housed in the housing 5 at such a position that the heat sink 28 faces the first air exhaust vents 26 and forms a first ventilation path 91a and a second ventilation path 91b, which are described later. In the first ventilation path 91a and the second ventilation path 91b, electronic parts are disposed.

As illustrated in FIG. 8, the CPU 41 is connected to the heat sink 28 with the heat dissipation plate 35 and the heat pipe 34 interposed therebetween. The heat pipe 34 is an example of a heat transport member. The heat pipe 34 extends from the CPU 41 to the heat sink 28. The heat pipe 34 thermally connects the CPU 41 to the heat sink 28 and transfers heat of the CPU 41 to the heat sink 28. That is, the heat pipe 34 connects the electronic part to the heat sink 28.

The heat dissipation plate 35 is a metal plate member, for example. The heat dissipation plate 35 has a first section 35a that faces the CPU 41 and is thermally connected to the CPU 41. The heat dissipation plate 35 is not thermally connected to the power source circuit part 43, for example.

As illustrated in FIG. 4, the ODD 32 is housed on the right side of the housing 5, which is opposite the circuit board 31. The storage device 33 is a hard disk drive (HDD), for example. The storage device 33 is disposed at the front edge 14 of the housing 5, adjacent to the fan 24. The storage device 33 comprises a case 51 and a magnetic disk (not illustrated) housed in the case 51. A side surface 51a (an edge surface) of the case 51 extends in a plane-like fashion and faces the side of the fan 24. The side surface 51a of the case 51 forms an upright wall that faces the fan 24 on the side that is opposite the left side wall 8c of the housing 5.

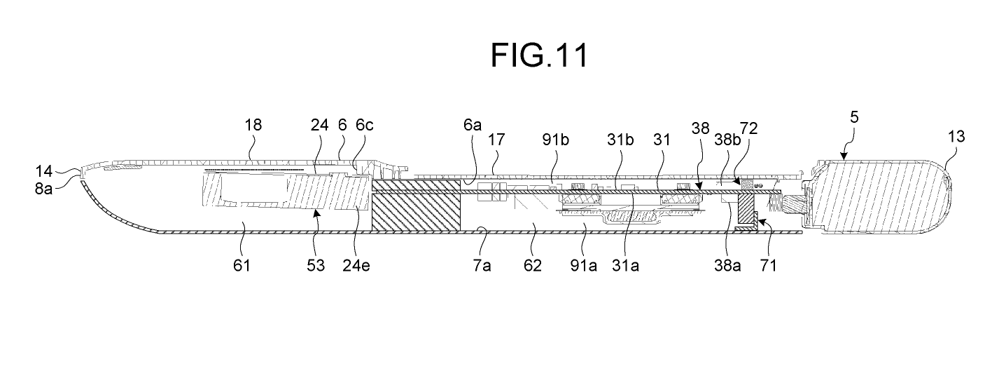

As illustrated in FIG. 8, the fan 24 is disposed away from the heat sink 28 at the front edge 14 on the left side of the housing 5, for example. As illustrated in FIG. 10, the fan 24 is disposed under the palm rest 18. That is, the fan 24 is not disposed under the keyboard placement section 17 where the thickness of the housing 5 is relatively small, but is disposed under the palm rest 18 where the thickness of the housing 5 is relatively large. As illustrated in FIG. 10, respective gaps are provided between the fan 24 and the lower wall 7 of the housing 5, and between the fan 24 and the upper wall 6 of the housing 5. As illustrated in FIG. 11, an opposing portion 6c is provided to the upper wall 6, which faces the upper portion of a rear edge 24e of the fan 24, of the housing 5 so as to overlap with the rear edge 24e in the up-down direction. The opposing portion 6c reduces a gap between a first chamber 61 and a second chamber 62, which are described later.

The fan 24, which is a centrifugal fan, comprises a fan case 53 and an impeller 54 rotated in the fan case 53. The fan case 53 comprises a first suction vent 24a, a second suction vent 24b, and the discharge outlet 24c.

As illustrated in FIG. 10, the fan case 53 comprises a lower surface 53a facing the lower wall 7, an upper surface 53b that is located opposite the lower surface 53a and faces the upper wall 6, and a peripheral surface 53c facing the circuit board 31. The first suction vent 24a is provided to the lower surface 53a of the fan case 53 and faces the first air intake vents 21 of the lower wall 7. The second suction vent 24b is provided to the upper surface 53b of the fan case 53 and opens toward a side opposite the first suction vent 24a. The second suction vent 24b faces the palm rest 18 with a gap between itself and the palm rest 18. An uneven section 53d is formed on the upper surface 53b so as to fit the shape of the housing 5. The thickness of the uneven section 53d reduces as the housing 5 extends toward the edge. In this way, the fan case 53 comprises the lower surface 53a and the upper surface 53b as a pair of opposing surfaces facing the inner surface of the housing 5 and the peripheral surface 53c that is the side surface provided between the pair of opposing surfaces (the lower surface 53a and the upper surface 53b).

As illustrated in FIG. 10, the discharge outlet 24c opens in the first direction D1 as described above and faces the CPU 41 of the circuit board 31. The thickness of the discharge outlet 24c is larger than that of the circuit board 31. The circuit board 31 is disposed close to the upper surface 53b in the thickness direction of the discharge outlet 24c, and faces the discharge outlet 24c.

That is, the discharge outlet 24c opens in a range from the upper side to the lower side of the circuit board 31 in the thickness direction of the discharge outlet 24c. The discharge outlet 24c has a first section 24ca located on the first surface 31a side of the circuit board 31 and a second section 24cb located on the second surface 31b side of the circuit board 31.

The fan 24 sucks air from the housing 5 through the first suction vent 24a and the second suction vent 24b, and discharges the sucked air through the discharge outlet 24c toward the CPU 41. The fan 24 thus discharges the air toward the upper and lower sides of the circuit board 31.

As illustrated in FIG. 12, the thickness of the heat sink 28 is larger than that of the circuit board 31. The circuit board 31 is disposed close to the upper edge of the heat sink 28 in the thickness direction of the heat sink 28 and faces the heat sink 28.

That is, the heat sink 28 is exposed on the upper and lower sides of the circuit board 31. The heat sink 28 has a first section 28a located on the first surface 31a side of the circuit board 31 and a second section 28b located on the second surface 31b side of the circuit board 31. The first section 28a is exposed to air flowing toward the first surface 31a of the circuit board 31. The second section 28b is exposed to air flowing toward the second surface 31b of the circuit board 31.

As illustrated in FIGS. 8 and 10, the edge of the circuit board 31, which faces the discharge outlet 24c of the fan 24, has a non-mounting area 56. The non-mounting area 56 has a width of 5 mm, for example, and extends along the side edge of the circuit board 31 and in the width direction of the discharge outlet 24c. The non-mounting area 56 serves as a margin for being put on a rail of a mounter in a mounting process, such as a reflow process, in which parts are mounted on the circuit board. The non-mounting area 56, in which no parts are mounted, hardly hinders a flow of air discharged from the fan 24.

As illustrated in FIG. 8, the electronic apparatus 1 comprises a wind shield 64 that partitions the inside of the housing 5 into the first chamber 61 (a first region), the second chamber 62 (a second region), and a third chamber 63 (a third region). The first chamber 61 is an air suction chamber from which the fan 24 sucks fresh air. The second chamber 62, in which parts generating a relatively large amount of heat are mounted in a concentrated manner, is a duct through which cooling wind is supplied from the fan 24 mainly toward the heat sink 28. In the third chamber 63, parts generating a relatively small amount of heat are housed, for example. The term “chamber” indicates a region (an area) in the housing 5 and is not always required to be thoroughly shielded from the other chambers (the other regions).

As illustrated in FIGS. 6 to 8, in the embodiment, the wind shield 64 comprises a first wall 71, a second wall 72, a third wall 73, and a fourth wall 74. The first wall 71, the second wall 72, the third wall 73, and the fourth wall 74 correspond to guiding walls. The first wall 71, the second wall 72, the third wall 73, and the fourth wall 74 correspond to wind guiding members.

The first wall 71 is provided between the inner surface 7a of the lower wall 7 and the first section 38a of the circuit board device 38. The inner surface 7a serves as an upper inner surface of the housing 5. The first wall 71 abuts the first section 38a. The first wall 71 forms the first ventilation path 91a, which extends from the discharge outlet 24c of the fan 24 to the first air exhaust vents (exhaust holes) 26 and the second air exhaust vents 27 through the first section 38a side of the circuit board device 38.

The first wall 71 comprises a first section 71a and a second section 71b. The first section 71a extends from near the right portion of the discharge outlet 24c of the fan 24 to near the rear portion of the heat sink 28 through an area between the memory slot connector 44 and the CPU 41. The second section 71b extends from near the left portion of the discharge outlet 24c of the fan 24 to near the front portion of the heat sink 28. A part of the first section 71a of the first wall 71 is disposed apart from the discharge outlet 24c of the fan 24 at a position facing the discharge outlet 24c.

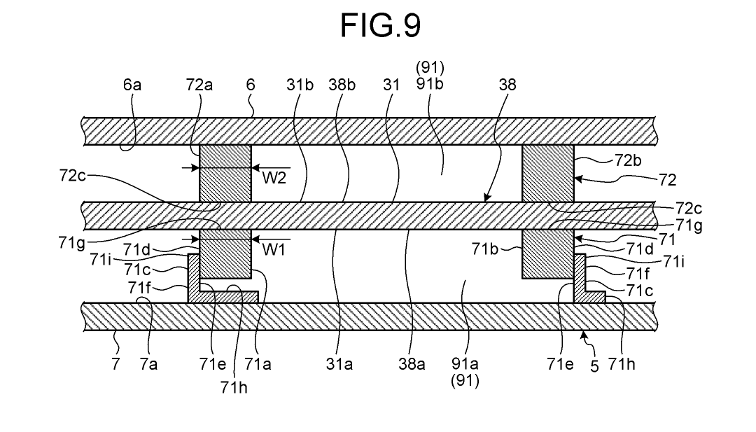

As illustrated in FIG. 9, the first wall 71 comprises a first member 71c and a second member 71d. The first member 71c is provided to the inner surface 7a, which is the inner surface of the housing 5, of the lower wall 7 by being welded, for example. The first member 71c is fixed to the inner surface 7a of the lower wall 7. The first wall 71 comprises a portion formed to have a section in an L-character shape. The portion having the section in the L-character shape of the first wall member has a first wall 71k fixed to the inner surface 7a of the lower wall 7 and a second wall 71j provided to the edge of the first wall 71k in a protruded manner. The first wall 71 is made of a resin, for example. In other words, the first wall 71 is made of plastic, for example. The first member 71c functions as a vertical wall and increases the stiffness of the housing 5. The first member 71c differs from the lower wall 7 of the housing 5 in material. In FIG. 9, the electronic parts are not illustrated.

The second member 71d is attached to the first member 71c by a double-sided adhesive tape, for example. The second member 71d abuts the circuit board device 38. The tip of the second member 71d abuts the electronic parts mounted on the circuit board device 38. The electronic parts have relatively low profiles and the heights thereof are within a certain range. The stiffness of the second member 71d is lower than that of the first member 71c. The second member 71c is made of an elastic member such as a sponge or rubber. The secondmember 71d is attached to a first side surface 71e, which is a side surface of the first member 71c. Specifically, the first member 71c has the first side surface 71e forming the first ventilation path 91a and a second side surface 71f, which is the surface opposite the first side surface 71e. The second member 71d is attached to the first side surface 71e. The first wall 71 has a first abutting surface 71g that abuts the first section 38a of the circuit board device 38 and extends along the first section 38a at the tip of the second member 71d. The second member 71b is located away from the inner surface of the housing 5.

A communicating hole 92 that communicates inside and outside of the first ventilation path 91a in the housing 5 is provided at a position between a part of the first wall 71a and the inner surface 7a of the lower wall 7, which is the inner surface of the housing 5. Specifically, the second member 71d is not provided to a part of the first section 71a facing the memory slot connector 44 of the first wall 71a. Therefore, the communicating hole 92 is provided between the first member 71c and the inner surface 7a of the lower wall 7. The communicating hole 92 communicates between the second chamber 62 and the third chamber 63.

The second wall 72 is provided between the inner surface 6a of the upper wall 6, which is the inner surface of the housing 5, and the second section 38b of the circuit board device 38. The second wall 72 abuts the second section 38b of the circuit board device 38 and is disposed so as to overlap with the first wall 71 with the circuit board device 38 interposed therebetween. The second wall 72 forms the second ventilation path 91b, which extends from the discharge outlet 24c of the fan 24 to the first air exhaust vents 26 and the second air exhaust vents 27 through the second section 38b side of the circuit board device 38. The second ventilation path 91b and the first ventilation path 91a form a ventilation path 91.

The second wall 72 comprises a first section 72a and a second section 72b. The first section 72a extends from near the right portion of the discharge outlet 24c of the fan 24 to near the rear portion of the heat sink 28 along the first section 71a of the first wall 71. The second section 72b extends from near the left portion of the discharge outlet 24c of the fan 24 to near the front portion of the heat sink 28 along the second section 71b of the first wall 71. A part of the first section 72a of the second wall 72 is disposed apart from the discharge outlet 24c of the fan 24 at such a position that the part faces the discharge outlet 24c. The second wall 72 is provided to the inner surface 6a of the upper wall 6, which is the upper inner surface of the housing 5, by a double-sided adhesive tape, for example. The second wall 72 is made of an elastic member such as a sponge or rubber. The height of the second wall 72 is lower than that of the first wall 71. The second wall 72 has a second abutting surface 72c that abuts the second section 38b of the circuit board device 38 and extends along the second section 38b. A first width W1 of the first abutting surface 71g in a direction orthogonal to an extending direction of the first abutting surface 71g of the first wall 71 (the left-right direction in FIG. 9) is approximately equal to a second width W2 of the second abutting surface 72c in a direction orthogonal to the extending direction of the second abutting surface 72c (the left-right direction in FIG. 9).

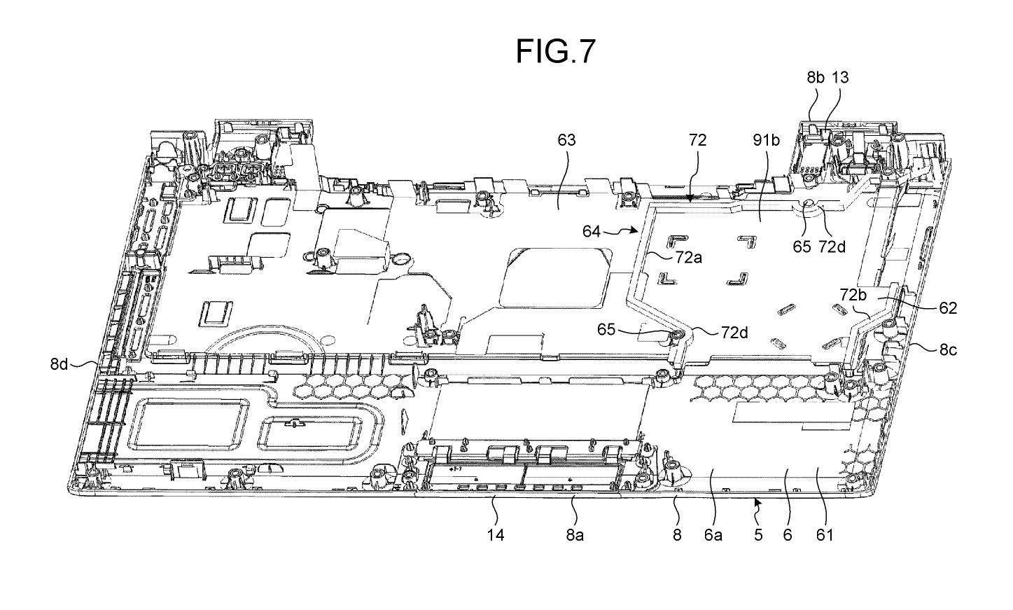

As illustrated in FIG. 7, first protrusions 65 are provided in a protruded manner to the inner surface 6a of the upper wall 6, which is the inner surface of the housing 5. The first protrusions 65 are bosses that support the circuit board 31, for example. The second wall 72 has bent portions 72d bent (curved) along the first protrusions 65. The first protrusions 65 are located outside the bent portion 72d (outside the second ventilation path 91b). The first protrusions 65 may be located inside the bent portion 72d (inside the second ventilation path 91b). The first protrusions 65 may be provided in a protruded manner to the inner surface 7a of the lower wall 7. In this case, the first wall 71 has the bent portions bent (curved) along the first protrusions 65.

As illustrated in FIG. 6, a second protrusion 66 is provided in a protruded manner to the inner surface 7a of the lower wall 7, which is the inner surface of the housing 5. The second protrusion 66 forms the first ventilation path 91a and is comprised in the wind shield 64. The second protrusion 66 is the boss that supports the circuit board 31, for example. The edge of the first member 71c of the first section 71a of the first wall 71 is formed in a shape along the second protrusion 66. The second protrusion 66 may be provided in a protruded manner to the inner surface 6a of the upper wall 6 and may form the second ventilation path 91b.

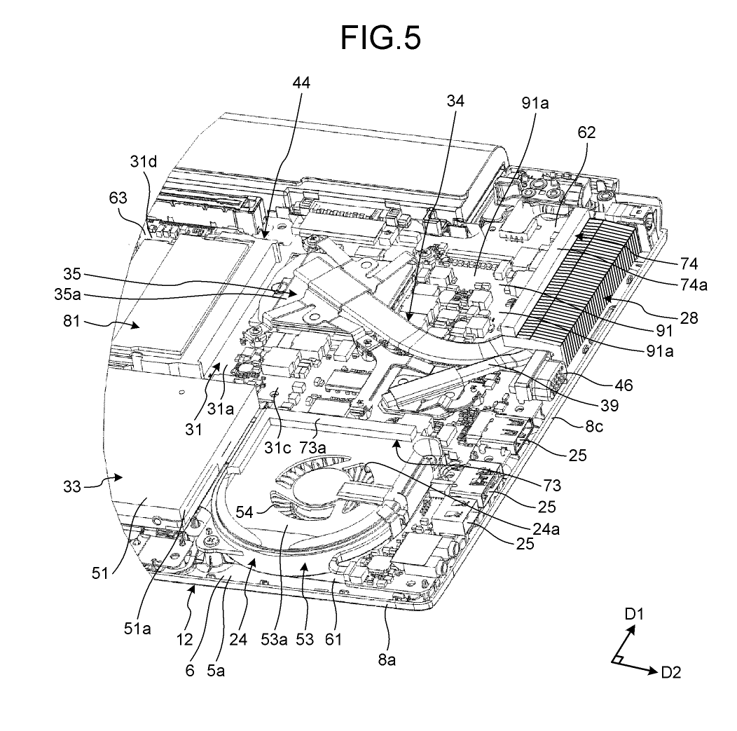

As illustrated in FIGS. 5 and 10, the third wall 73 is provided between the fan case 53 of the fan 24 and the inner surface of the housing 5. The third wall 73 comprises a first section 73a and a second section 73b. The first section 73a is provide between the lower surface 53a, which is one of the pair of opposing surfaces of the fan case 53, and the inner surface 7a of the lower wall 7, which is the inner surface of the housing 5. The second section 73b is provide between the upper surface 53b, which is the other of the pair of opposing surfaces of the fan case 53, and the inner surface 6a of the upper wall 6, which is the inner surface of the housing 5. The first section 73a and the second section 73b are made of an elastic member such as a sponge or rubber. The first section 73a and the second section 73b are attached to the fan case 53 by a double-sided adhesive tape, for example.

As illustrated in FIG. 12, the fourth wall 74 is provided between the heat sink 28 and the inner surface of the housing 5. The fourth wall 74 comprises a first section 74a and a second section 74b. The first section 74a is provided between the lower surface of the heat sink 28 and the inner surface 7a of the lower wall 7. The second section 74b is provided between the upper surface of the heat sink 28 and the inner surface 6a of the upper wall 6. The first section 74a and the second section 74b are made of an elastic member such as a sponge or rubber. The first section 74a and the second section 74b are attached to the heat sink 28 by a double-sided adhesive tape, for example.

The first wall 71, the second wall 72, the third wall 73, and the fourth wall 74 are examples of a non-conductive member (insulator). In FIG. 8, the parts comprised in the wind shield 64 are illustrated by being hatched for expository convenience.

A wind shield structure of the first chamber 61 is described below. As illustrated in FIG. 8, the first section 73a a of the third wall 73 is attached to the lower surface 53a of the fan 24. The first section 73a extends in the width direction of the discharge outlet 24c (the second direction D2) along the discharge outlet 24c of the fan 24. That is, the first section 73a is provided between the first suction vent 24a and the discharge outlet 24c and partitions the space in the housing 5. The first section 73a also extends in the first direction D1 along the right edge of the fan 24. The first section 73a is located on a side, which is opposite the left side wall 8c of the housing 5, of the first suction vent 24a of the fan 24. That is, the first suction vent 24a of the fan 24 is located between the first section 73a and the left side wall 8c of the housing 5. In this way, the first section 73a extends in approximately an L-character shape.

As illustrated in FIG. 10, the second section 73b of the third wall 73 is formed on the upper surface 53b of the fan 24 in approximately a plane symmetry with the first section 73a. That is, the first section 73a and the second section 73b are disposed so as to overlap with each other in the up-down direction with the fan case 53 interposed therebetween. The second section 73b extends in the width direction of the discharge outlet 24c along the discharge outlet 24c of the fan 24. The second section 73b is provided between the second suction vent 24b and the discharge outlet 24c and partitions the space in the housing 5. The second section 73b also extends in the first direction D1 along the right edge of the fan 24. The second section 73b is provided between the upper surface 53b of the fan 24 and the inner surface (the inner surface of the palm rest 18) of the upper wall 6 of the housing 5. In this way, the second section 73b extends in approximately an L-character shape. The third wall 73 is compressed in a gap between the fan case 53 and the inner surface of the housing 5 and hermetically seals the gap.

As a result, as schematically illustrated in FIG. 14, the first chamber 61 surrounded by the third wall 73, and the left side wall 8c and the front wall 8a of the housing 5 is formed at the corner of the housing 5. That is, the third wall 73 partitions the inside of the housing 5 into the first chamber 61 and the second chamber 62.

In the embodiment, the third wall 73 is not provided to an area off the fan 24, but is provided on the surface of the fan 24. That is, the third wall 73 separates, not fully but partially, the first chamber 61 in the housing 5.

The third wall 73 may extend to the region off the fan 24 and fully separate the first chamber 61 from the other regions in the housing 5. In the embodiment, the side surface 51a of the case 51 of the storage device 33 functions as a secondary wall to form a part of the wall of the first chamber 61.

As illustrated in FIGS. 8 and 10, in the first chamber 61, the first air intake vents 21, the second air intake vents 22 and the third air intake vents 23 of the housing 5, and the first suction vent 24a and the second suction vent 24b of the fan 24 are exposed. In the first chamber 61, the heating elements mounted on the circuit board 31 are not disposed. The first chamber 61 communicates with the outside of the housing 5 through the first air intake vents 21, the second air intake vents 22, and the third air intake vents 23. Fresh air, thus, can flow into the first chamber 61. Because of the structure, a temperature of air in the first chamber 61 is lower than those of air in the other chambers.

A wind shield structure of the second chamber 62 (the duct) is described below. As illustrated in FIG. 8, the second chamber 62 is separated from the first chamber 61 and the third chamber 63 by the first wall 71 and the second wall 72, for example. In the second chamber 62, the heating elements such as the CPU 41 are disposed. The first wall 71 forms the first ventilation path 91a of the ventilation path 91, which has a duct structure through which cooling wind flows toward the heat sink 28 from the fan 24, together with the lower wall 7 of the housing 5. The second wall 72 forms the second ventilation path 91b (refer to FIG. 10) of the ventilation path 91 having the duct structure through which cooling wind flows toward the heat sink 28 from the fan 24, together with the upper wall 6 of the housing 5. The first ventilation path 91a is formed on the first surface 31a of the circuit board 31 (i.e., between the circuit board 31 and the lower wall 7 of the housing 5) in approximately an L-character shape. The second ventilation path 91b is formed on the second surface 31b of the circuit board 31 (i.e., between the circuit board 31 and the upper wall 6 of the housing 5) in the same approximate L-character shape as the first ventilation path 91a. The first ventilation path 91a and the second ventilation path 91b are formed in approximately a plane symmetry with respect to the circuit board 31. The first wall 71 is compressed in a gap between the inner surface of the housing 5 and the circuit board device 38 and hermetically seals the gap. As a result, cooling wind discharged by the fan 24 arrives at the heat sink 28 by being guided by the first wall 71 and the like.

As illustrated in FIG. 8, the CPU 41, the power source circuit parts, the heat pipe 34, and the heat dissipation plate 35 are located in the first ventilation path 91a.

Air discharged from the first section 24ca of the discharge outlet 24c of the fan 24 flows through the first ventilation path 91a and arrives at the first section 28a of the heat sink 28. Air discharged from the second section 24cb of the discharge outlet 24c of the fan 24 flows through the second ventilation path 91b and arrives at the second section 28b of the heat sink 28. A gap between the second surface 31b of the circuit board 31 and the upper wall 6 of the housing 5 is smaller than that between the first surface 31a and the lower wall 7 of the housing 5. In this way, the electronic parts such as the CPU 41, the heat pipe 34, and the heat sink 28 are cooled by cooling wind flowing through the first ventilation path 91a and the second ventilation path 91b.

Meanwhile, part of the cooling wind flows into the third chamber 63 through the communicating hole 92, thereby cooling a memory 81 in the third chamber 63, for example. The memory slot connector 44 holding the memory 81 is disposed away from the inner surface of the housing 5, thereby avoiding transfer of heat of the memory slot connector 44 to the housing 5. The third chamber 63 communicates with the outside of the housing 5 though ventilation holes provided to the lower wall 7 of the housing 5. As illustrated in FIG. 4, in the third chamber 63, the PCH 42, the memory 81, the ODD 32, and the storage device 33 are exposed. The PCH 42 and the memory 81, which are provided with no heat dissipation members, dissipate heat naturally.

The first section 31c of the circuit board 31 is exposed in the second chamber 62. The second section 31d of the circuit board 31 is exposed in the third chamber 63. In the embodiment, the parts do not fully but partially separate the third chamber 63 from the other regions in the housing 5. The third chamber 63 may be fully separated from the other regions in the housing 5.

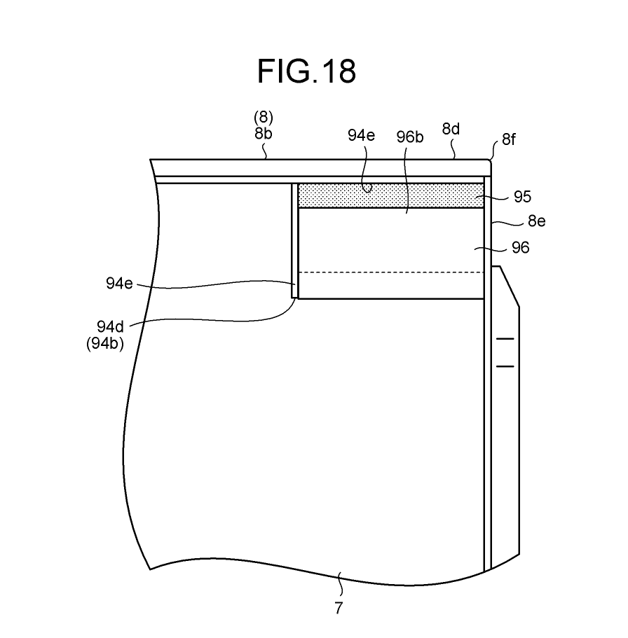

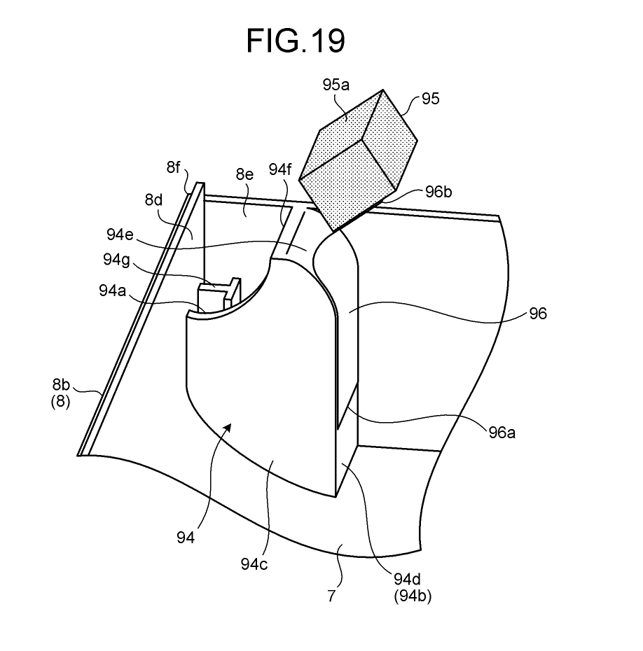

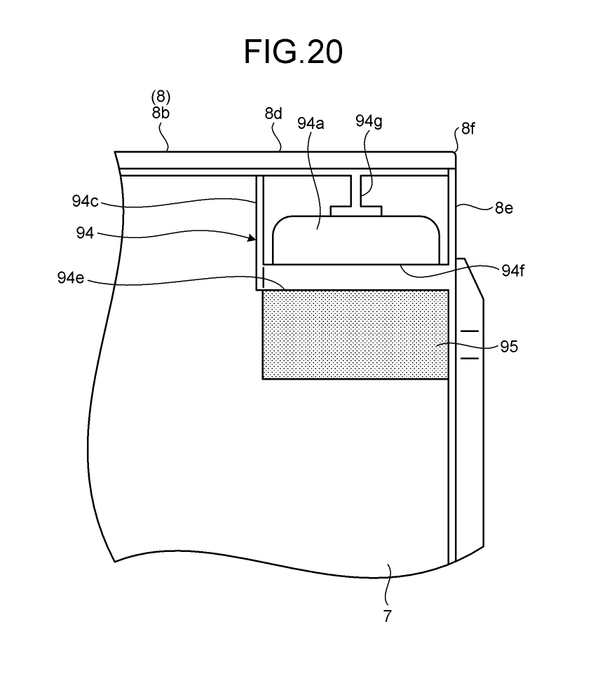

As illustrated in FIGS. 6 and 17 to 20, the lower wall 7 is provided with an engaging portion 94 along the rear wall 8b of the peripheral wall 8. The engaging portion 94 forms a part of the housing 5. The engaging portion 94 is provided with an opening 94a (a through hole), to which a hook (an engaging portion, not illustrated) of a dock (a supporter or a connection) to which the electronic apparatus 1 is attached, is engaged (inserted) from below.

The engaging portion 94 comprises walls 8d, 8e, 94b, and 94c. The walls 8d and 8e are comprised in the rear wall 8b. The walls 8d and 8e are jointed at a corner 8f. The wall 94b faces the wall 8b while the wall 94b faces the wall 8e. The opening 94a is surrounded by the walls 8d, 8e, 94b, and 94c and penetrates the lower wall 7. That is, the opening 94a communicates the inside and outside of the housing 5. The opening 94a is an example of the openings provided to the housing 5.

An elastic member 95 is put in (set in) the opening 94a. The elastic member 95 is made of a sponge or rubber, for example. The elastic member 95 plugs the opening 94a. The elastic member 95 is supported by a sheet 96 (a first member or an insulator).

The sheet 96 is provided at such a position in the housing 5 that the sheet 96 covers at least a part of the opening 94a. The sheet 96 can be made of a resin, for example. The sheet 96 is a sheet-shaped member having flexibility. The sheet 96 is fixed to the engaging portion 94 of the housing 5. One edge 96a of the sheet 96 is fixed to the housing 5 while the other edge 96b of the sheet 96 is fixed to the elastic member 95. The fixings are achieved using an adhesive, for example. The one edge 96a of the sheet 96 is fixed to the wall 94b. Specifically, the wall 94b has a surface 94d and a curved section 94e. The surface 94d extends along an axial direction of the opening 94a (in the embodiment, in the up-down direction). The sheet 96 is fixed to the surface 94d. The curved section 94e connects an edge 94f of the opening 94a and the surface 94d. The sheet 96 overlaps with the curved section 94e. The curved section 94e enables the sheet 96 to make good close contact with the wall 94b.

The engaging portion 94 is provided with a supporter 94g. The supporter 94g is located in the opening 94a. The supporter 94g supports a portion 95a, which is opposite the sheet 96, of the elastic member 95.

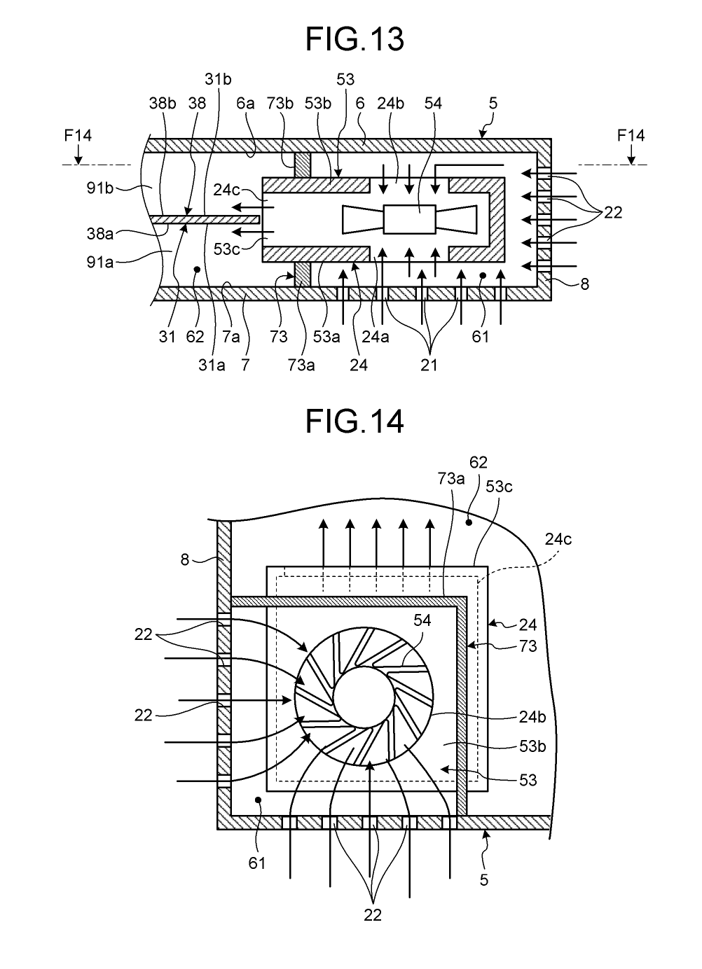

Operation of the electronic apparatus 1 is described below with reference to FIGS. 13 to 15 schematically illustrating the structure of the electronic apparatus 1 of the embodiment.

As illustrated in FIGS. 13 and 14, the inside of the housing 5 is partitioned into the first chamber 61 and the second chamber 62. The structure (the third wall 73) that blocks air flow between the first chamber 61 and the second chamber 62 is provided therebetween. The first suction vent 24a and the second suction vent 24b of the fan 24 are exposed in the first chamber 61. The discharge outlet 24c of the fan 24 is exposed in the second chamber 62. That is, a partially closed region that surrounds the first suction vent 24a and the second suction vent 24b of the fan 24 is provided at the corner in the housing 5.

The fan 24 sucks air from outside the housing 5 into the first chamber 61 and discharges air toward the second chamber 62 from the first chamber 61. The suction vents of the fan 24 are not exposed in the second chamber 62 and the third chamber 63. As a result, the fan 24 rarely or seldom sucks air warmed by the CPU 41, the PCH 42, the power source circuit part 43, and the other heating elements in the second chamber 62 and the third chamber 63.

The fan 24 sucks low temperature air outside the housing 5 through the first chamber 61 and discharges the low temperature air into the second chamber 62 toward the CPU 41, for example. Although the air intake vents are provided to the lower wall 7 and the peripheral wall 8 of the housing 5 in the embodiment, the air intake vents of the housing 5 may be provided to at least any one of the upper wall 6, the lower wall 7, and the peripheral wall 8.

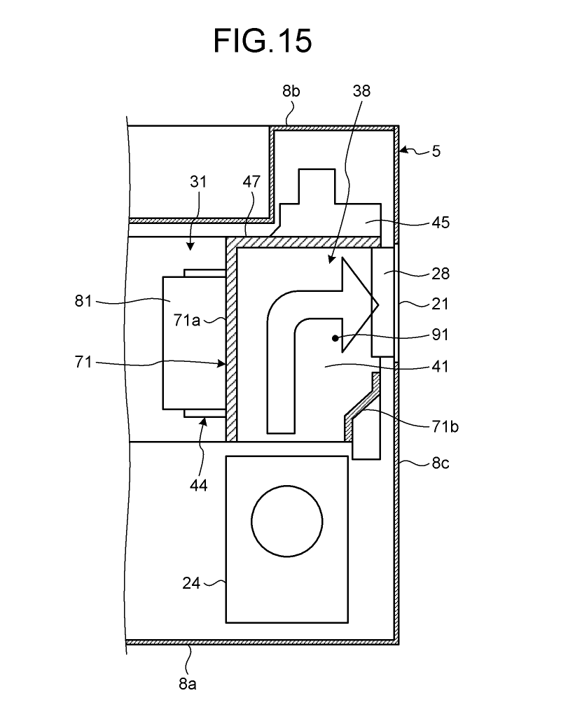

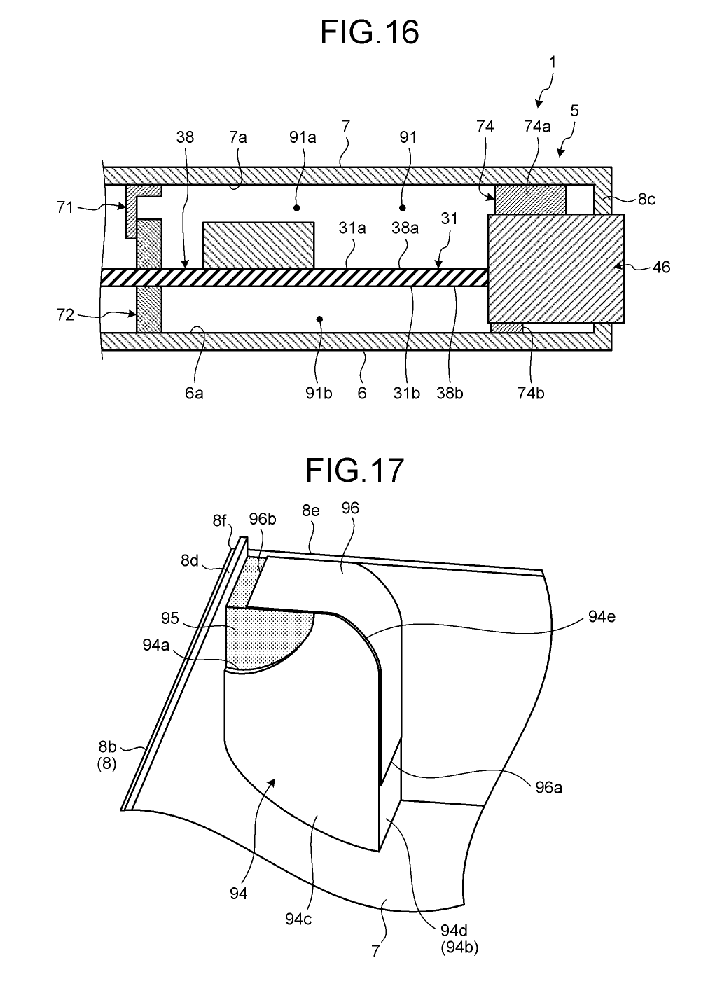

As exemplarily illustrated in FIGS. 15 and 16, the ventilation path 91 (the first ventilation path 91a and the second ventilation path 91b) guiding cooling wind from the fan 24 toward the heat sink 28 is formed in the housing 5 by the board-like parts mounted on the circuit board 31. Specifically, both side walls of the ventilation path 91 are formed by the first wall 71. That is, the ventilation path 91 is the space surrounded by the first wall 71, the circuit board device 38, and the lower wall 7 and the upper wall 6 (or the keyboard 9) of the housing 5.

As a result, cooling wind discharged from the fan 24 flows over the circuit board device 38 toward the heat sink 28 from the fan 24 along the arrow indicated in FIG. 15. That is, cooling wind discharged from the fan 24 flows steadily and in a focused manner to the CPU 41, the heat sink 28 and the like, without being dispersed in the housing 5, thereby efficiently cooling the CPU 41, the heat sink 28, and the like.

Hence, the structure can increase cooling efficiency. As an example of the air intake structures, suppose a structure in which the suction vents provided to the lower surface of the fan, face the air intake vents provided to the lower wall of the housing, and the suction vents provided to the upper surface of the fan open in the housing. In this case, the suction vents provided to the lower surface of the fan can suck low temperature fresh air while the suction vents provided to the upper surface of the fan suck warmed air from the housing 5. Because of the structure, air discharged from the fan 24 has a certain degree of temperature. As a result, the heat sink 28 exposed by such air may not be efficiently cooled, for example.

In contrast, in the structure of the embodiment, the wind shield 64, which at least partially separates the space in the housing 5, is provided between the discharge outlet 24c and the suction vents 24a and 24b of the fan 24. The structure causes air discharged from the discharge outlet 24c and warmed by the CPU 41 and the heat sink 28 to be hardly sucked through the suction vents 24a and 24b again. The structure thus enables air having a relatively low temperature to be supplied to the CPU 41 and the heat sink 28, thereby enabling heat dissipation efficiency to be increased.

In the embodiment, the wind shield 64 is provided that at least partially separates, in the housing 5, the first chamber 61 in which the air intake vents 21, 22, and 23 of the housing 5 and the suction vents 24a and 24b of the fan 24 are exposed and the second chamber 62 in which the air exhaust vents 26 and 27 of the housing 5, the CPU 41, the heat sink 28, the heat pipe 34, and the discharge outlet 24c of the fan 24 are exposed. As a result, air warmed by the CPU 41, the heat sink 28, and the heat pipe 34 hardly flows back to the suction vents 24a and 24b of the fan 24.

Particularly, in the embodiment, the first chamber 61 is provided into which surrounding fresh air is sucked and in which the first suction vent 24a of the upper surface 53a and the second suction vent 24b of the lower surface 53b of the fan 24 are exposed. The heating elements such as the CPU 41 are housed in the second chamber 62 separated from the first chamber 61. The structure enables the second suction vent 24b provided to the upper surface 53a of the fan 24 to suck not warmed air from the housing 5 but low temperature fresh air in the same manner as the first suction vent 24a provided to the lower surface 53b of the fan 24.

The structure enables air having a relatively low temperature to be supplied to the CPU 41 and the heat sink 28, thereby enabling heat dissipation efficiency to be further increased. In other words, the structure includes the fan 24 provided inside the housing 5 for sucking air from outside the housing 5 and exhausting (supplying) the sucked air into the housing 5 as thoroughly as possible, regardless of the type of fan.

The fan 24 has a relatively larger height (thickness) among the parts housed in the housing 5. The disposition of the fan 24 under the palm rest 18 enables the housing 5 to be formed to have a smaller thickness by utilizing the space under the palm rest 18, which is larger than the space under the keyboard placement section 17 with regard to the thickness of the housing 5, thus being able to house the fan 24.

As an example of the air intake structures, suppose again a structure in which the suction vents provided to the lower surface of the fan face the air intake vents provided to the lower wall of the housing, and the suction vents provided to the upper surface of the fan open in the housing. In this case, when the air intake vents provided to the lower wall of the housing are blocked due to any cause, the suction vents provided to the lower surface of the fan also suck warmed air from the housing. As a result, the cooling efficiency may be lowered.

In contrast, in the embodiment, the housing 5 is provided with the first chamber 61 for sucking air, which comprises the second air intake vents 22 in addition to the first air intake vents 21. In the structure, the first chamber 61 communicates with the outside of the housing 5 even if the first air intake vents 21 are blocked. In addition, the suction vents 24a and 24b of the fan 24 are exposed in the first chamber 61, thereby enabling low temperature fresh air to be sucked from the first chamber 61. Because of the structure, the cooling efficiency is hardly lowered even if some of the air intake vents of the housing 5 are blocked.

Particularly, the first air intake vents 21 are provided to the lower wall 7 of the housing 5 and the second air intake vents 22 are provided to the peripheral wall 8 of the housing 5, and it is less possible that both of the air intake vents 21 and 22 are blocked simultaneously, thereby causing the first chamber 61 to readily communicate with the outside of the housing 5.

Furthermore, the second heating element (e.g., the PCH 42) that sufficiently cools through natural heat dissipation is comprised, and the wind shield 64 at least partially separates the third chamber 63 in which the second heating element is disposed from the first chamber 61 and the second chamber 62 in the housing 5. As a result, cooling wind of the fan 24 can be discharged to the second chamber 62 in a focused manner and air warmed in the third chamber 63 is hardly sucked by the fan 24. Consequently, the cooling efficiency in the entire apparatus can be increased.

In the embodiment, as illustrated in FIG. 8, the CPU 41 is located at an outer circumferential area in the first ventilation path 91a having an L-character shape in the second chamber 62. Therefore, to supply high speed cooling wind to the CPU 41, the impeller 54 of the fan 24 is rotated in a direction along which the impeller 54 rotates toward an inner circumferential area of the first ventilation path 91a from the outer circumferential area of the first ventilation path 91a (direction indicated with an arrow X in FIG. 8) when viewed from the discharge outlet 24c. As a result, the cooling efficiency for the CPU 41 increases.

In the embodiment, as illustrated in FIG. 8, the heat pipe 34 is curved in such a shape that the heat pipe 34 approaches the fan 24 at a part in its route from the CPU 41 to the heat sink 28, and is connected to the edge on the fan 24 side of the heat sink 28. This shape enables cooling wind to be efficiently supplied to the heat pipe 34. The heat pipe 34 may be formed in such a shape that the heat pipe 34 increases the distance between itself and the fan 24 as the heat pipe 34 extends in its route from the CPU 41 to the heat sink 28. An example of the shape is illustrated in FIG. 8. In this case, cooling wind can be supplied to the heat sink 28 at a large flow rate.

In the embodiment, the first wall 71 and the second wall 72, which are disposed so as to sandwich the circuit board device 38 in the housing 5, correspond to a pair of walls guiding cooling wind. The first wall 71 comprises the second section 71b serving as an elastic portion abutted to the circuit board device 38 and the first section 71a that is attached to the inner surface of the housing 5 and serves as the supporter supporting the second section 71b. The first wall 71 is provided so as to be sandwiched between the inner surface of the housing 5 and the circuit board device 38 while the second section 71b is being elastically deformed. The first wall 71 corresponds to the wall guiding cooling wind.

The circuit board device 38 is a board, a circuit board, a circuit plate, a wiring board on which parts are mounted, a housed part, or a module, in other words. The first member 71c is a supporter, a wall, a rib, a protruded portion, a projection, a protrusion, a holding portion, or a part of the wind guiding member, in other words. The ventilation path 91 (the first ventilation path 91a and the second ventilation path 91b) is a wind guiding path, a region, a first region, a space surrounded by the board, the inner wall of the housing 5, and the wind guiding members (the first wall 71, the second wall 72, the third wall 73, and the fourth wall 74), or a space between the fan 24 and the air exhaust vents 26 and 27. The wind guiding members (the first wall 71, the second wall 72, the third wall 73, and the fourth wall 74) are walls, ribs, protruded portions, projections, holding portions, parts of the wind guiding members, or deformable members or materials having flexibility and elasticity. The second member 71d, which serves as the wind guiding member, has lower stiffness than that of the first member 71c. The up, down, left, and right described above can be reworded as the first, second, third, and fourth. The up and the down can be reworded as one and the other. The left and the right can be reworded as one and the other.

In the embodiment, the first wall 71 serving as the wall comprises the first member 71c provided to the inner surface of the housing 5 and the second member 71d that is attached to the first member 71c, abutted to the circuit board device 38, and has lower stiffness than that of the first member 71c, and is provided between the inner surface of the housing 5 and the circuit board device 38. The structure can prevent the second member 71d from collapsing because of the cooling wind by suppressing load applied to the circuit board device 38 with the second member 71d and supporting the second member 71d tightly with the second member 71c. According to the embodiment, an increase in load applied to the circuit board 31 can be suppressed when the cooling efficiency of the fan 24 is intended to be increased.

In the embodiment, the first wall 71 forming the first ventilation path 91a and the second wall 72 forming the second ventilation path 91b are disposed so as to overlap with each other with the circuit board device 38 interposed therebetween. As a result, application of shearing force to the circuit board device 38 between the first wall 71 and the second wall 72 can be suppressed. According to the embodiment, an increase in load applied to the circuit board 31 can be suppressed when the cooling efficiency of the fan 24 is intended to be increased. When the first wall 71 and the second wall 72 forming the second ventilation path 91b are disposed so as not to overlap with each other, but so as to be shifted from each other, shearing force is applied to the circuit board device 38.

In the embodiment, the elastic member 95 is set in the opening 94a provided to the housing 5 and the sheet 96 supporting the elastic member 95 is provided in the housing 5 at such a position that the sheet 96 covers at least a part of the opening 94a. According to the embodiment, air hardly flows into the opening 94a because the opening 94a is well plugged. That is, the elastic member 95 and the sheet 96 achieve high sealing property for the opening 94a. Even when part of cooling wind flowing toward the heat sink 28 from the fan 24 flows (leaks) toward the opening 94a, for example, the cooling wind arriving at the opening 94a can be prevented from leaking outside the housing 5 from the opening 94a. As a result, a reduction in a volume of wind flowing toward the first air exhaust vents 26 and the second air exhaust vents 27 can be suppressed, thereby enabling the cooling efficiency of the fan 24 to be increased corresponding to the saved volume.

In the embodiment, the elastic member 95 is supported by the sheet 96 having flexibility, thereby enabling the elastic member 95 to be readily positioned and attached. In addition, the elastic member 95 is attached to the housing 5 with the sheet 96 interposed therebetween, thereby enabling the elastic member 95 to be better supported.

Modifications of the first embodiment are described below. Structures having the same or similar functions as the first embodiment are labeled with the same numeral, and description thereof is omitted. Structures excluded from the description below are the same as in the first embodiment.

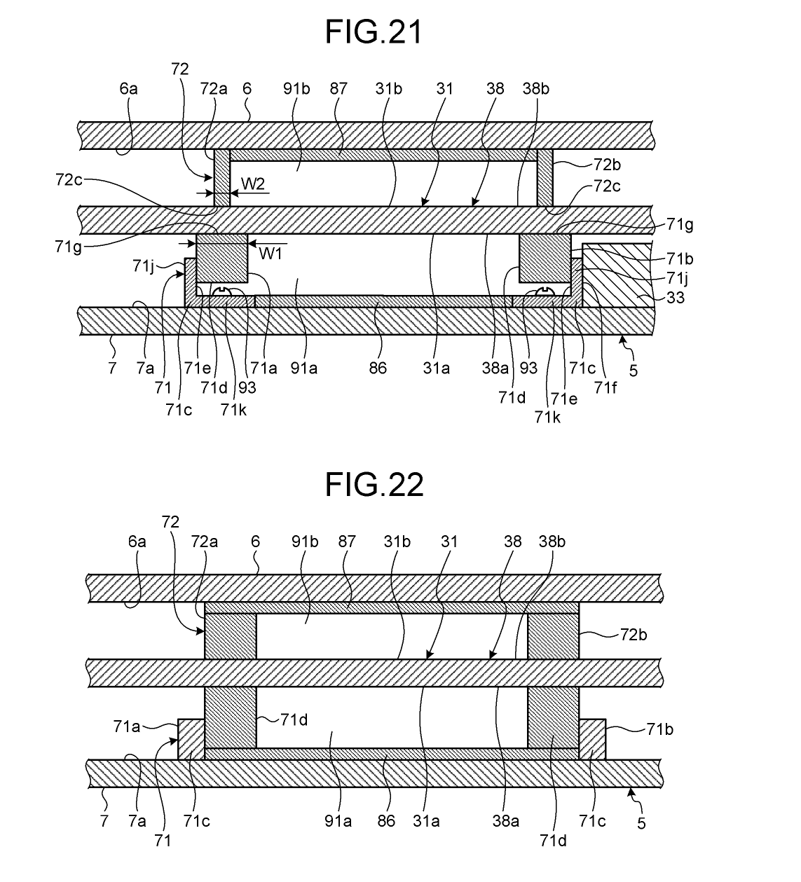

A first modification is described with reference to FIG. 21. In the first modification, one of the first width W1 of the first abutting surface 71g in the direction orthogonal to the extending direction of the first abutting surface 71g of the first wall 71 (in the left-right direction in FIG. 21) and the second width W2 of the second abutting surface 72c in the direction orthogonal to the extending direction of the second abutting surface 72c of the second wall 72 (in the left-right direction in FIG. 21) is wider than the other. In the first modification, the first width W1 of the first abutting surface 71g is wider than the second width W2 of the second abutting surface 72c. This setting enables the second wall 72 and the first wall 71 to be disposed so as to overlap with each other by absorbing an error in the shapes of the second wall 72 and the first wall 71.

The first member 71c of the second section 71b of the first wall 71 serves as the wall to support the storage device 33 and supports the storage device 33. The first member 71c serves as the wall to position the storage device 33 and positions the storage device 33. The storage device 33 is an example of the parts or modules supported or positioned by the first member 71c.

In the first modification, a first insulator 86 serving as a platy member and a second insulator 87 serving as the platy member are provided. The first insulator 86 and the second insulator 87 are the platy members having insulating property. The first insulator 86 and the second insulator 87 also have heat blocking property and sound blocking property. The first insulator 86 is attached to the inner surface 7a of the lower wall 7 by a double-sided adhesive tape, for example, between the first section 71a and the second section 71b of the first wall 71. The second insulator 87 is attached to the inner surface 6a of the upper wall 6 by a double-sided adhesive tape, for example, between the first section 72a and the second section 72b of the second wall 72.

In the first modification, the first member 71c of the first wall 71 is fixed to the inner surface 7a of the lower wall 7 by screws 93. Specifically, the first wall 71k of the first member 71c is fixed to the inner surface 7a of the lower wall 7 by the screws 93. That is, the first member 71c is threadably mounted on the lower wall 7. The first member 71c can be tightly fixed to the lower wall 7 by fixing first member 71c to the lower wall 7 by the screws 93 as described above. In the example illustrated in FIG. 21, the first member 71c can be readily fixed to the lower wall 7 by attaching the second member 71d to the first member 71c by a double-sided adhesive tape after the first member 71c is fixed to the lower wall 7 by the screws 93, for example.

A second modification is described with reference to FIG. 22. In the second modification, the first insulator 86 is disposed between the second member 71d of the first wall 71 and the inner surface 7a of the lower wall 7. That is, the first insulator 86 serving as the platy member is attached to the inner surface of the housing 5 so as to be interposed between the inner surface of the housing 5 and the second member 71d. The second insulator 87 is disposed between the second wall 72 and the inner surface 6a of the upper wall 6. That is, the second wall 72 is attached to the housing 5 with the second insulator 87 interposed therebetween.

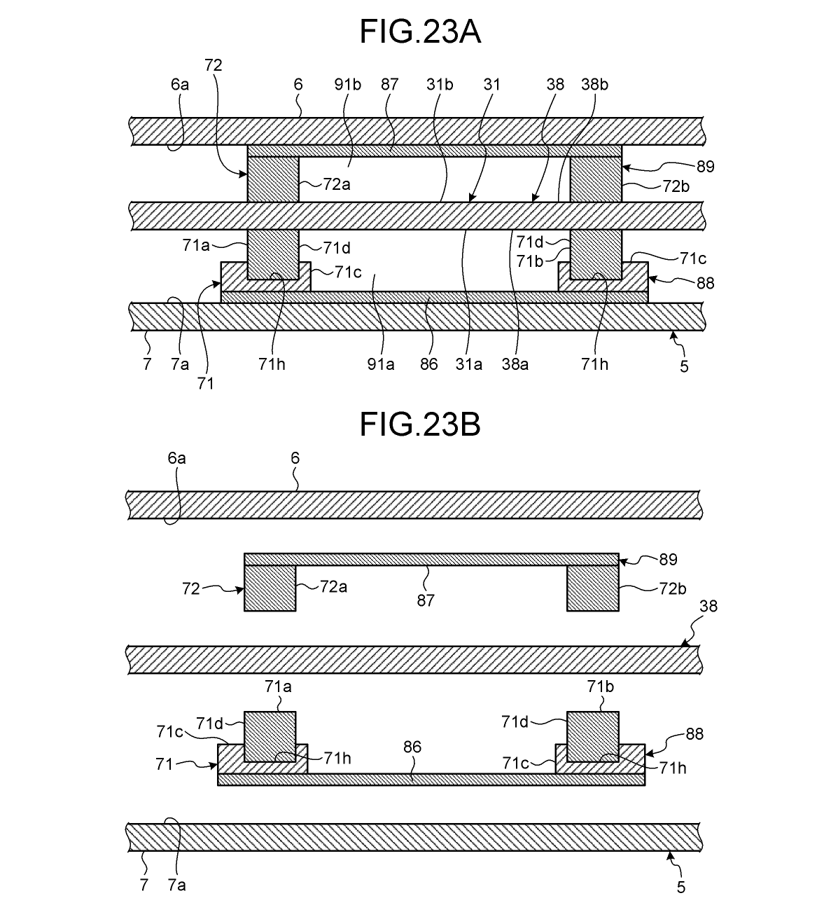

A third modification is described with reference to FIGS. 23A and 23B. In the third modification, the first insulator 86 is preliminarily attached to the first wall 71 so as to be a wall unit 88. The first insulator 86 is attached to the first member 71c by a double-sided adhesive tape, for example. The first insulator 86 is attached to the housing 5 by a double-sided adhesive tape, for example. In the third modification, the wall unit 88 comprises the first wall 71 and the first insulator 86 that serves as the platy member and is attached to the first member 71c, and the first insulator 86 is attached to the inner surface of the housing 5.

The second insulator 87 is preliminarily attached to the second wall 72 so as to be a wall unit 89. The second insulator 87 is attached to the second wall 72 by a double-sided adhesive tape, for example. The second insulator 87 is attached to the housing 5 by a double-sided adhesive tape, for example. In the third modification, the wall unit 89 comprises the second insulator 87 that serves as the platy member and is attached to the second wall 72, and the second insulator 87 is attached to the inner surface of the housing 5.

This structure enables the first wall 71 and the second wall 72 to be readily attached to the housing 5.

The first member 71c of the first wall 71 is provided with an insert receiving portion 71h into which the second member 71d is inserted. The insert receiving portion 71h is formed in a groove shape. As a result, the second member 71d can be readily attached to the first member 71c and tightly supported by the first member 71c.

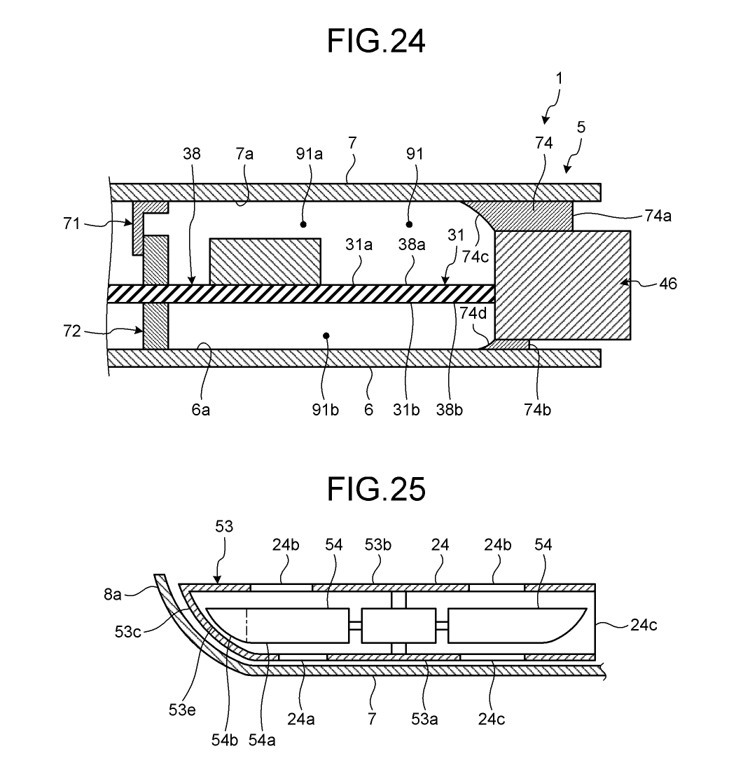

A fourth modification is described with reference to FIG. 24. In the fourth modification, the first section 74a and the second section 74b of the fourth wall 74 have extensions 74c and 74d extending from the heat sink 28 side to the circuit board 31 side, respectively. The extensions 74c and 74d are formed in such a tapered and curved shape that the thicknesses thereof are reduced as they extend in their extending directions. The shape reduces resistance of the fourth wall 74 against cooling wind, thereby enabling higher speed cooling wind to be efficiently guided to the heat sink 28.

A fifth modification is described with reference to FIG. 25. In the fifth modification, the fan case 53 of the fan 24 is curved along the front wall 8a of the housing 5 and the impeller 54 has a portion having a curved shape along the curvature of front wall 8a. Specifically, the fan case 53 has a curved section 53e curved along the curvature of front wall 8a on the peripheral wall 53c. The impeller 54 has a base 54a having a rectangular shape and an extension 54b extending from the base 54a toward the peripheral wall 53c. The extension 54b has such a curved shape along the curvature of front wall 8a that the thickness of the extension 54b is reduced as the extension 54b extends toward the tip thereof.

According to the structure, the extension 54b having the curved shape along the curvature of front wall 8a is extended from the base 54a, thereby enabling a wind volume supplied by the impeller 54 to be increased corresponding to the extension 54b.

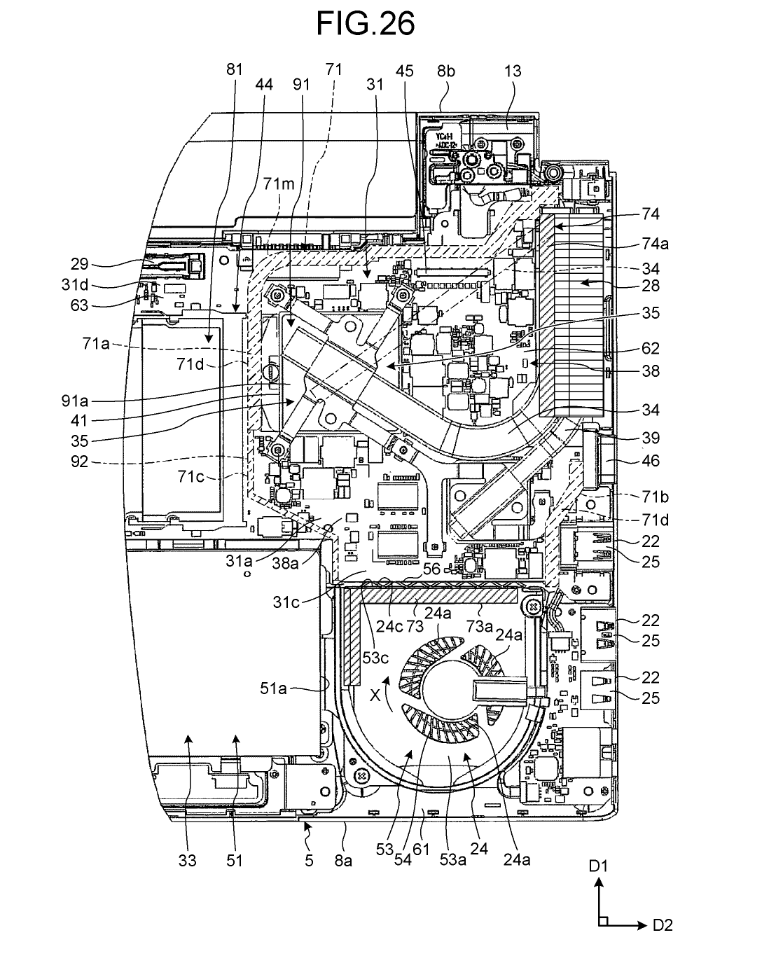

A sixth modification is described with reference to FIG. 26. In the sixth modification, a curved portion 71m is formed at the corner of the ventilation path 91, which has an L-character shape and comprises the first wall 71 and the second wall 72 (not illustrated). This structure can reduce resistance of the ventilation path 91 against cooling wind flowing through the ventilation path 91.

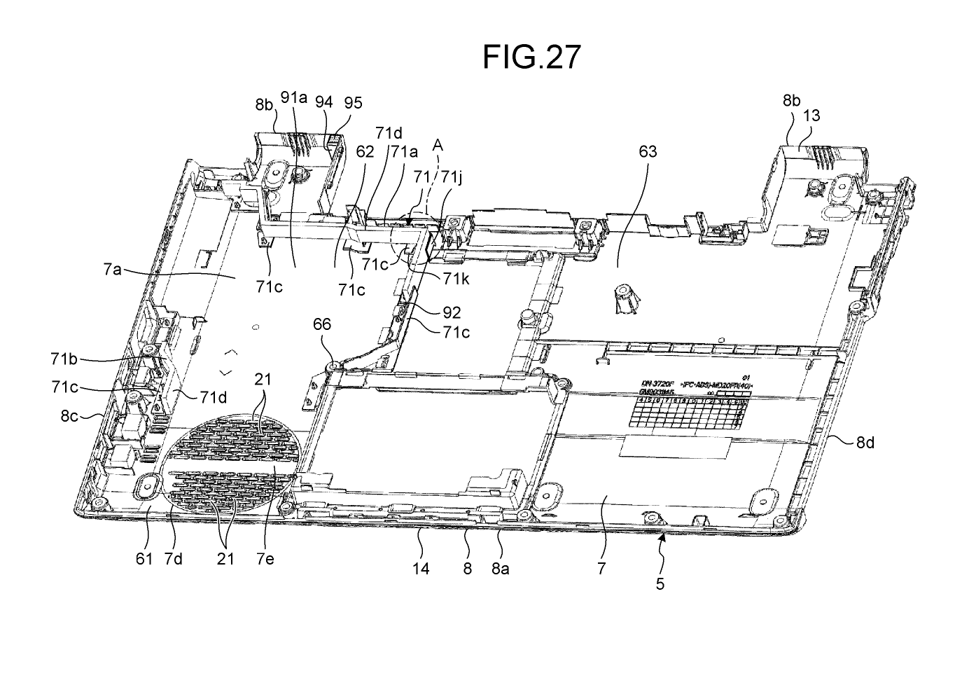

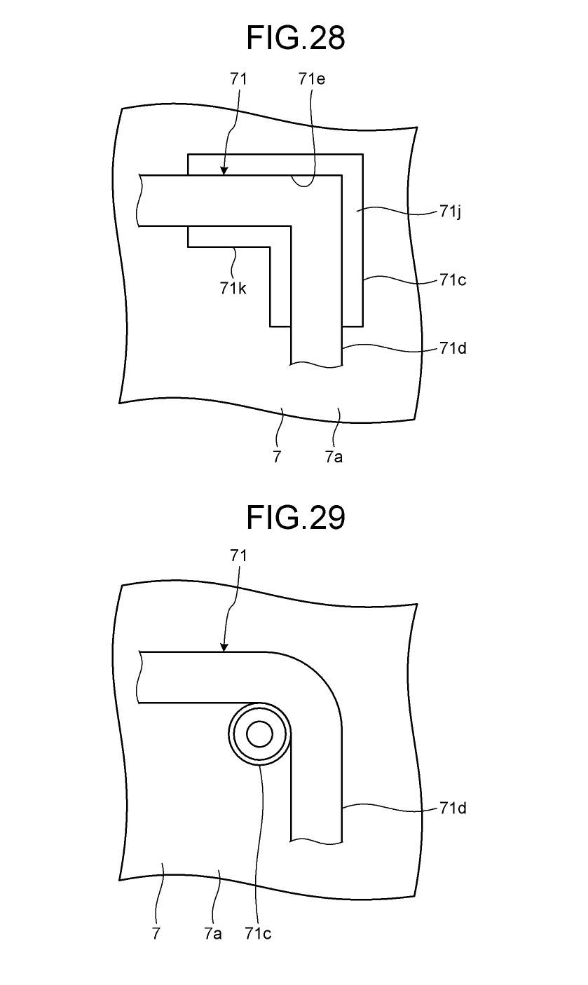

A seventh modification is described with reference to FIGS. 27 and 28. As illustrated in FIG. 27, in the seventh modification, a plurality of first members 71c are provided so as to be apart from each other in the first section 71a of the first wall 71. In other words, the first section 71a is provided by being divided. The first members 71c are provided partially at the corners (corner portions or bent portions, in other words) of the first wall 71. The first members 71c are provided at the ends of the first wall 71 in the extending directions of the first wall 71. The second member 71d connects between the first members 71c. The second member 71d closes the spaces between the first members 71c. As illustrated in FIG. 28, the extending direction of one of the first members 71c extending along the inner surface 7a of the lower wall 7 is bent, for example. The second member 71d is disposed on the inner circumferential side of the first member 71c, specifically, on the inner circumferential side of the second wall 71j. In this way, the second member 71d may be disposed on the inner circumferential side of the first member 71c, specifically, on the inner circumferential side of the second wall 71j. In the seventh modification, the first section 71a having an L-character shape illustrated in FIG. 9 is exemplified. The seventh modification is not limited to being applied to the example, and may be applied to the first section 71a having an upright wall illustrated in FIG. 22 and the first section 71a having the insert receiving portion 71h having a groove shape illustrated in FIG. 23A. That is, the first member 71c may be located on one side or both sides in the width direction of the second member 71d.

The first members 71c are thus provided so as to be apart from each other and at the corners of the first wall 71 as described above, whereby the second member 71d can be supported satisfactorily while the weight of the first wall 71 is reduced.

An eighth modification is described with reference to FIG. 29. FIG. 29 illustrates an area in the electronic apparatus 1 corresponding to the area illustrated in FIG. 28. In the eighth modification, the first wall 71 is basically the same as that of the seventh modification but differs from that of the seventh modification in that the first section 71a is replaced with a third protrusion (hereinafter, referred to as a third protrusion 71a). The third protrusion 71a serving as the first section 71a is provided to the inner surface 7a of the lower wall 7 in a protruded manner. The third protrusion 71a is a boss supporting parts such as the circuit board 31 in the housing 5, for example. In the eighth modification, the third protrusion 71a substitutes the first section. The second member 71d curves along the outer circumference of the third protrusion 71a. That is, the third protrusion 71a is located on the inner circumferential side of the corner of the second member 71d. In other words, the third protrusion 71a is located at the inside corner of the second member 71d. The protrusion is, in other words, a projection or a protruded portion.

The third protrusion 71a is thus located on the inner circumferential side of the corner of the second member 71d as described above, whereby the second member 71d can be attached to the third protrusion 71a by being adhesively bonded to the third protrusion 71a while being winded around the third protrusion 71a, for example. That is, the second member 71d can be readily attached. In this structure, the third protrusion 71a and the second member 71d need not be adhesively bonded because the second member 71d is positioned by being hooked to the third protrusion 71a.

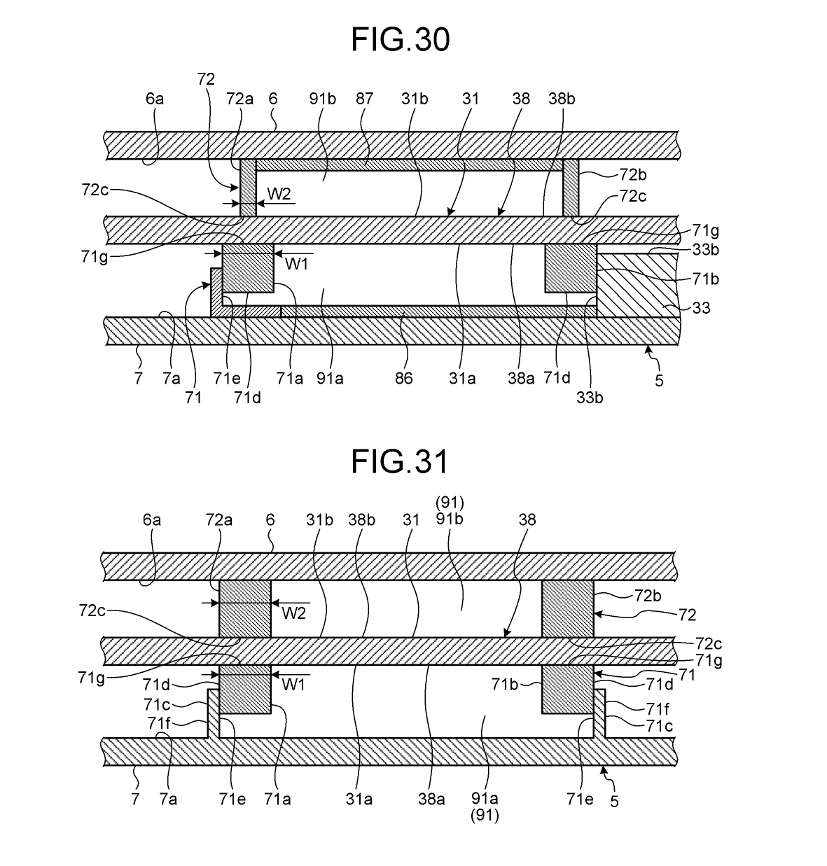

A ninth modification is described with reference to FIG. 30. In the ninth modification, the case 33 of the storage device 33 (e.g., HDD) functions as the first member of the second section 72b of the first wall 71. That is, a side surface 3b of a case 33a of the storage device 33 supports the second member 71d of the second section 72b. The second member 71d is attached to the side surface 3b of the case 33a by a double-sided adhesive tape, for example. The storage device 33 is an example of the parts having a relatively large height. The storage device 33 is an example of the modules. That is, the second member 71d is not limited to being attached to the first member 71c and may be attached to another part. That is, the part functions as a compatible module that doubles as the first member 71c and is used as the substitution of the first member 71c. The compatible module has both of a first function and a second function that supports the second member 71d. The first function is the function that houses and protects the storage section of the storage device 33 in the case 33a of the storage device 33.

The second member 71d is thus attached to the case 33 serving as the compatible module of the storage device 33 as describe above, whereby the duct structure can be relatively simple and inexpensive. The compatible module is not limited to the storage device 33. For example, the fan case 53 and the case of the ODD 32 may be used as the compatible module.

A tenth modification is described with reference to FIG. 31. In the tenth modification, the first member 71c of the first wall 71 is integrally formed with the inner surface 7a of the lower wall 7, which is the inner surface of the housing 5. The first member 71c is a rib (a protrusion or a projection) protruded from the inner surface 7a of the lower wall 7, for example. The housing 5 and the first member 71c are integrally formed using resin. Because the first member 71c is integrally formed with the inner surface 7a of the lower wall 7 as described above, the stiffness of the housing 5 is further increased. In addition, a worker's load can be reduced because work to attach the first member 71c to the inner surface 7a of the lower wall 7 is not required.

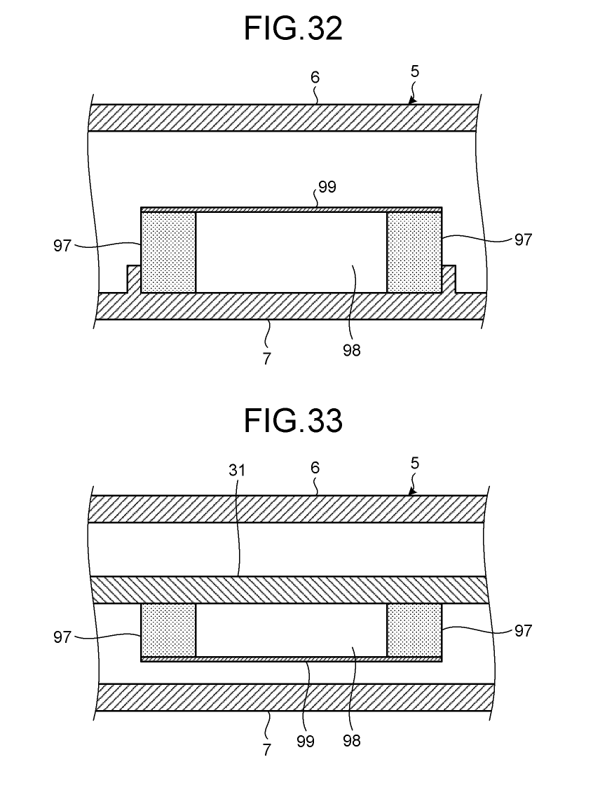

An eleventh modification is described with reference to FIG. 32. In the eleventh modification, a ventilation path 98 is provided between two (a plurality of) walls 97 provided to the lower wall, for example. The walls 97 are made of a sponge (elastic member), for example. A sheet 99 (a second member) is put over between the pair of walls 97. The sheet 99 forms the ventilation path 98. The sheet 99 is a sheet-shaped member having flexibility. The sheet 99 can be made of a resin, for example.

A twelfth modification is described with reference to FIG. 33. In the twelfth modification, the ventilation path 98 is provided between two (a plurality of) walls 97 provided to the circuit board 31, for example. The walls 97 are made of a sponge (elastic member), for example. The sheet 99 (the second member) is put over between the pair of walls 97. The sheet 99 forms the ventilation path 98. The sheet 99 is a sheet-shaped member having flexibility. The sheet 99 can be made of a resin, for example. The sheet 99 faces the circuit board 31.

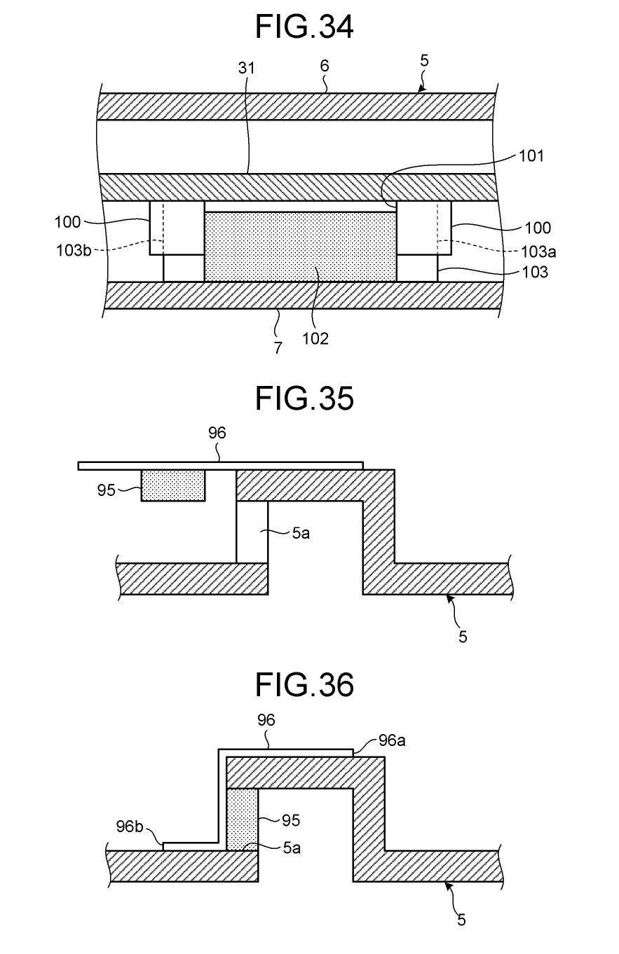

A thirteenth modification is described with reference to FIG. 34. In the thirteenth modification, an opening 101 (a first opening) is provided between two (a plurality of) parts 100 (e.g., electronic parts) provided in the housing 5. The parts 100 are mounted on a circuit board 6. An elastic member 102 is set in the opening 101. The elastic member 102 is made of a sponge or rubber, for example. The elastic member 102 plugs the opening 101. The elastic member 102 is supported by a sheet 103 (a first member or an insulator).

The sheet 103 is provided at such a position in the housing 5 that the sheet 96 covers at least a part of (in the modification, the whole of) the opening 101. The sheet 103 can be made of a resin, for example. The sheet 103 is a sheet-shaped member having flexibility. Edges 103a and 103b of the sheet 96 are fixed to the respective parts 100. The elastic member 102 is fixed between the edges 103a and 103b. The fixings are achieved using an adhesive, for example. The elastic member 102 and the sheet 103 can form a part of the ventilation path in the housing 5.

A fourteenth modification is described with reference to FIGS. 35 and 36. In the fourteenth modification, the elastic member 95 is set in an opening 5a provided to the housing 5 and fixed between the edges 96a and 96b of the sheet 96. The edges 96a and 96b of the sheet 96 are fixed to the housing 5. This structure enables the elastic member 95 to be more tightly fixed to the housing 5. FIG. 35 illustrates a state (a manufacturing step) before the elastic member 95 is set in the opening 5a.

### Second Embodiment

A television receiver 111 according to a second embodiment is described below. Structures having the same or similar functions as the first embodiment are labeled with the same numeral, and description thereof is omitted. Structures excluded from the description below are the same as in the first embodiment.

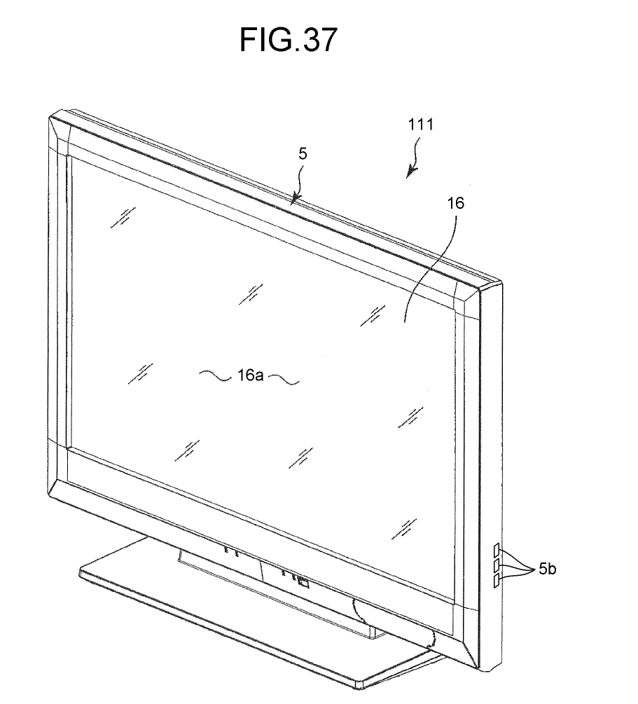

As illustrated in FIG. 37, the television receiver 111 comprises the housing 5 and the display panel 16 housed in the housing 5. The same structure as the first embodiment is provided in the housing 5.

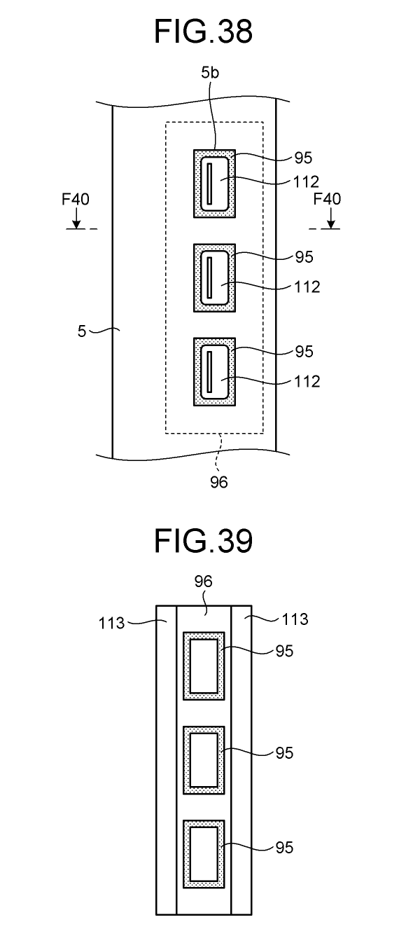

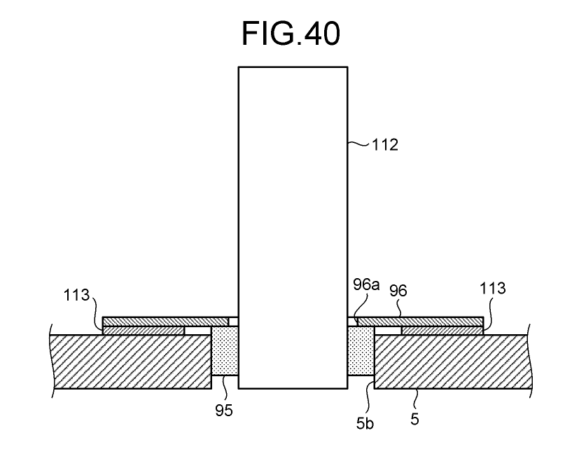

As illustrated in FIGS. 37 and 38, the housing 5 of the television receiver 111 is provided with a plurality of openings 5b (first openings or throughholes). Connectors 112 such as USB connectors are exposed through the openings 5b, for example.

The elastic member 95 is set in each opening 5b. The elastic member 95 fills the opening 5b surrounding the connector 112. The elastic member 95 is formed in a tubular shape and provided to the outside of the connector 11. As illustrated in FIG. 39, the elastic members 95 are fixed to the sheet 96 using an adhesive, for example. The sheet 96 is fixed to the inner surface of the housing 3 by an adhesive portion 113 such as an adhesive tape or a glue. The sheet 96 is provided with openings 96a into which the connectors 112 are inserted.

The television receiver 111 thus structured can increase the cooling efficiency in the same manner as the first embodiment.

### Third Embodiment

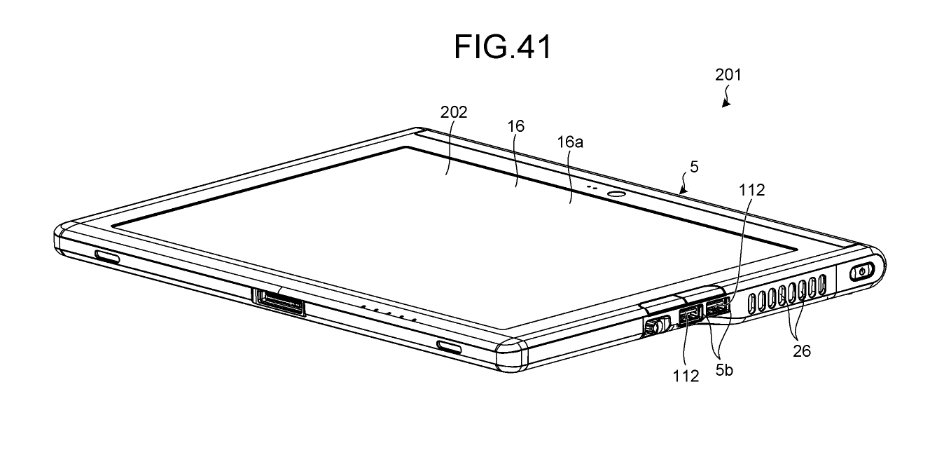

A third embodiment is described below. An electronic apparatus 201 of the third embodiment illustrated in FIGS. 41 and 42 is a so-called slate personal computer. As illustrated in FIG. 41, the electronic apparatus 201 is provided with a touch panel 202 formed in the shape of the display panel 16 housed in the housing 5. As illustrated in FIGS. 41 and 42, the housing 5 is provided with the first air exhaust vents 26, the openings 5b, and the first air intake vents 21, for example. The connectors 112 are exposed through the openings 5b. The same structure as the first embodiment is provided in the housing 5. The same structure as the second embodiment is provided in each opening 5b.

The electronic apparatus 201 thus structured can increase the cooling efficiency in the same manner as the first embodiment.

### Fourth Embodiment

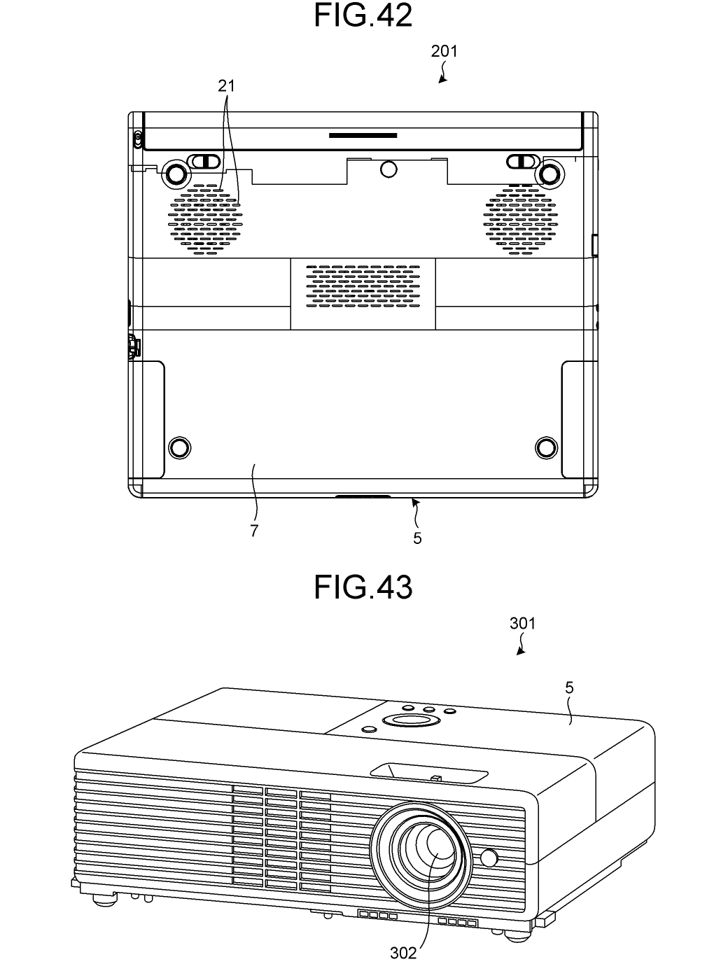

A fourth embodiment is described below. An electronic apparatus 301 of the fourth embodiment illustrated in FIG. 43 is a projector. The electronic apparatus 301 comprises the housing 5 and a lens exposed from the housing 5. The same structure as the first embodiment is provided in the housing 5.

The electronic apparatus 301 thus structured can increase the cooling efficiency in the same manner as the first embodiment.

According to the above-described embodiments, the cooling efficiency of the fan can be increased as described above.

Moreover, the various modules of the systems described herein can be implemented as software applications, hardware and/or software modules, or components on one or more computers, such as servers. While the various modules are illustrated separately, they may share some or all of the same underlying logic or code.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A television receiver comprising:
a housing comprising an air intake vent and an air exhaust vent;
a circuit board device in the housing;
a fan in the housing, the fan configured to supply airflow to the circuit board device;
an elastic member configured to be placed in an opening of the housing or inside the housing; and
a flexible sheet-like first member in the housing at a position where the flexible sheet-like first member covers at least apart of the opening, the flexible sheet-like first member configured to support the elastic member.

2. The television receiver of claim 1, wherein
the opening is configured to communicate inside and outside the housing, and
the flexible sheet-like first member is fixed to the housing.

3. The television receiver of claim 1, wherein one edge of the flexible sheet-like first member is fixed to the housing and another edge of the flexible sheet-like first member is fixed to the elastic member.

4. The television receiver of claim 1, wherein both edges of the flexible sheet-like first member are fixed to the housing, and the elastic member is fixed between the both edges.

5. The television receiver of claim 1, wherein the housing comprises:
a surface configured to extend along an axis direction of the opening, the surface fixed to the flexible sheet-like first member, and
a curved section configured to connect an edge of the opening and the surface, the flexible sheet-like first member overlaping the curved section.

6. The television receiver of claim 1, further comprising a support in the opening, the support configured to support a portion of the elastic member opposite the flexible sheet-like first member.

7. The television receiver of claim 1, further comprising a plurality of parts in the housing, wherein
the opening is between the plurality of parts, and
the flexible sheet-like first member is configured to be fixed to the plurality of parts.

8. The television receiver of claim 1, further comprising:
a pair of walls in the housing; and
a flexible sheet-like second member configured to be placed over the pair of walls.

9. The television receiver of claim 8, further comprising a circuit board configured to be housed in the housing, wherein
the flexible sheet-like second member is configured to face the circuit board.

10. An electronic apparatus comprising:
a housing comprising an air intake vent and an air exhaust vent;
a fan in the housing;
an elastic member configured to be placed in an opening of the housing or inside the housing; and
a flexible sheet-like member at a position where the flexible sheet-like member covers at least apart of the opening, the flexible sheet-like member configured to support the elastic member.
